(19) United States
(12) Patent Application Publication
(10) Pub. No.: US 2024/0128349 A1
(43) Pub. Date: Apr. 18, 2024

(54) SEMICONDUCTOR DEVICE AND MANUFACTURING METHOD OF SEMICONDUCTOR DEVICE

(71) Applicant: FUJI ELECTRIC CO., LTD., Kanagawa (JP)

(72) Inventors: Atsushi ONOGAWA, Matsumoto-city (JP); Kaname MITSUZUKA, Matsumoto-city (JP); Yuuki ODA, Matsumoto-city (JP); Tohru SHIRAKAWA, Matsumoto-city (JP)

(21) Appl. No.: 18/453,336

(22) Filed: Aug. 22, 2023

(30) Foreign Application Priority Data
Oct. 17, 2022 (JP) 2022-165979

(51) Int. Cl. H01L 29/66; H01L 29/08; H01L 29/739

(52) U.S. Cl. CPC H01L 29/66348; H01L 29/0821; H01L 29/7397

(57) ABSTRACT

Provided is a semiconductor device including: a drift region of a first conductivity type provided in a semiconductor substrate; a collector region of a second conductivity type provided on a back surface of the semiconductor substrate; a cathode region of the first conductivity type provided on the back surface of the semiconductor substrate and having a higher doping concentration than the drift region; a plurality of trench portions provided on a front surface of the semiconductor substrate; and a lifetime control portion provided in the semiconductor substrate and containing a lifetime killer, in which the lifetime control portion includes: a main region provided in a diode portion; and a decay region provided to extend from the main region in a direction parallel to the front surface of the semiconductor substrate and having a lifetime killer concentration that has decayed more than a lifetime killer concentration of the main region.

The contents of the following patent application(s) are incorporated herein by reference:
NO. 2022-165979 filed in JP on Oct. 17, 2022

### BACKGROUND

### 1. Technical Field

The present invention relates to a semiconductor device and a manufacturing method of a semiconductor device.

### 2. Related Art

Conventionally. there is known a semiconductor device including a transistor portion and a diode portion (see, for example, Patent Documents 1 to 3).
Patent Document 1: Japanese Patent Application Publication No. 2013-149909
Patent Document 2: WO 2012/169053
Patent Document 3: Japanese Patent Application Publication No. 2021-190496

### BRIEF DESCRIPTION OF THE DRAWINGS

FIG. 1A shows an example of a top view of a semiconductor device 100.

FIG. 1B is an enlarged view of a region A in FIG. 1A.

FIG. 2A is a diagram showing an example of an XZ cross section including a cross section a-a′ in FIG. 1B.

FIG. 2B is an example of a lifetime killer concentration in a cross section m-m′ in FIG. 2A.

FIG. 3A is an XZ cross section including the cross section a-a′ and shows a modified example of the semiconductor device 100.

FIG. 3B is an example of the lifetime killer concentration in the cross section m-m′ in FIG. 3A.

FIG. 4A is an XZ cross section including the cross section a-a′ and shows a modified example of the semiconductor device 100.

FIG. 4B is an example of the lifetime killer concentration in the cross section m-m′ in FIG. 4A.

FIG. 5A is an XZ cross section including the cross section a-a′ and shows a modified example of the semiconductor device 100.

FIG. 5B is an example of the lifetime killer concentration in the cross section m-m′ in FIG. 5A.

FIG. 6 shows an example of a doping concentration distribution in a buffer region 20.

FIG. 7A shows a relationship between a collector-emitter shutdown current Ices and an implantation region of a front surface side lifetime control region 151.

FIG. 7B shows a relationship between the collector-emitter shutdown current Ices and an implantation region of a back surface side lifetime control region 152.

FIG. 7C shows a relationship between a high-current short circuit withstand capability and the implantation region of the back surface side lifetime control region 152.

FIG. 8 shows an example of a helium ion implantation process that uses a mask 210.

FIG. 9A is a diagram for describing a diffusion half width at half maximum Wh by which a lifetime killer is diffused.

FIG. 9B is another example of the lifetime killer concentration distribution in the cross section m-m′ in FIG. 2A and the like.

FIG. 10 shows an example of a top view of the semiconductor device 100.

FIG. 11A is a top view showing a modified example of the semiconductor device 100.

FIG. 11B is a top view showing a modified example of the semiconductor device 100.

FIG. 11C is a top view showing a modified example of the semiconductor device 100.

FIG. 11D is a top view showing a modified example of the semiconductor device 100.

FIG. 12A is a top view showing a modified example of the semiconductor device 100.

FIG. 12B is a top view showing a modified example of the semiconductor device 100.

FIG. 12C is a top view showing a modified example of the semiconductor device 100.

FIG. 12D is a top view showing a modified example of the semiconductor device 100.

FIG. 13A is a top view showing a modified example of the semiconductor device 100.

FIG. 13B is a top view showing a modified example of the semiconductor device 100.

FIG. 13C is a top view showing a modified example of the semiconductor device 100.

FIG. 13D is a top view showing a modified example of the semiconductor device 100.

FIG. 14A is a top view showing a modified example of the semiconductor device 100.

FIG. 14B is a top view showing a modified example of the semiconductor device 100.

FIG. 14C is a top view showing a modified example of the semiconductor device 100.

FIG. 14D is a top view showing a modified example of the semiconductor device 100.

### DESCRIPTION OF EXEMPLARY EMBODIMENTS

Hereinafter, embodiments of the present invention will be described. However, the following embodiments are not for limiting the invention according to the claims. In addition, not all of the combinations of features described in the embodiments are essential to the solving means of the invention.

As used herein, one side in a direction parallel to a depth direction of a semiconductor substrate is referred to as “upper” and the other side is referred to as “lower”. One surface of two principal surfaces of a substrate, a layer, or other member is referred to as an upper surface, and the other surface is referred to as a lower surface. “Upper” and “lower” directions are not limited to a direction of gravity, or a direction in which a semiconductor device is mounted.

In the present specification, technical matters may be described using orthogonal coordinate axes of an X axis, a Y axis, and a Z axis. The orthogonal coordinate axes specify relative positions of components, and do not limit a specific direction. For example, the Z axis is not limited to indicate the height direction with respect to the ground. Note that a +Z axis direction and a −Z axis direction are directions opposite to each other. When the Z axis direction is described without the signs, it means that the direction is parallel to the +Z axis and the −Z axis.

In the present specification, orthogonal axes parallel to the upper surface and the lower surface of the semiconductor substrate are referred to as the X axis and the Y axis. Further, an axis perpendicular to the upper surface and the lower surface of the semiconductor substrate is referred to as the Z axis. In the present specification, the direction of the Z axis may be referred to as the depth direction. Further, in the present specification, a direction parallel to the upper surface and the lower surface of the semiconductor substrate may be referred to as a horizontal direction, including an X axis direction and a Y axis direction.

In the present specification, a case where a term such as “same” or “equal” is mentioned may include a case where an error due to a variation in manufacturing or the like is included. This error is, for example, within 10%.

In the present specification, a conductivity type of a doping region where doping has been carried out with an impurity is described as a P type or an N type. In the present specification, the impurity may particularly mean either a donor of the N type or an acceptor of the P type, and may be described as a dopant. In the present specification, doping means introducing the donor or the acceptor into the semiconductor substrate and turning it into a semiconductor showing a conductivity type of the N type, or a semiconductor showing a conductivity type of the P type.

In the present specification, a doping concentration means a concentration of the donor or a concentration of the acceptor in a thermal equilibrium state. In the present specification, a net doping concentration means a net concentration obtained by adding the donor concentration set as a positive ion concentration to the acceptor concentration set as a negative ion concentration, taking polarities of charges into account. As an example, when the donor concentration is referred to as N_{D} and the acceptor concentration is referred to as N_{A}, the net doping concentration at any position is given as N_{D}−N_{A}. In the present specification, the net doping concentration may simply be referred to as the doping concentration.

The donor has a function of supplying electrons to a semiconductor. The acceptor has a function of receiving electrons from the semiconductor. The donor and acceptor are not limited to the impurities themselves. For example, a VOH defect which is a combination of a vacancy (V), oxygen (O), and hydrogen (H) existing in the semiconductor, an Si-i-H defect which is a combination of interstitial silicon (Si-i) and hydrogen, or a CiOi-H defect which is a combination of interstitial carbon (Ci), interstitial oxygen (Oi), and hydrogen functions as the donor that supplies electrons. In the present specification, these defects may be referred to as the hydrogen donor.

A P+ type or an N+ type described in the present specification means a doping concentration higher than that of the P type or the N type, and a P− type or an N− type described herein means a doping concentration lower than that of the P type or the N type. Furthermore, a P++ type or an N++ type described in the present specification means a higher doping concentration than that of the P+ type or the N+ type.

A chemical concentration in the present specification indicates an atomic density of an impurity measured regardless of an electrical activation state. The chemical concentration can be measured by, for example, secondary ion mass spectrometry (SIMS). The net doping concentration described above can be measured by capacitance-voltage profiling method (CV method). Furthermore, a carrier concentration measured by a spreading resistance profiling method (SRP method) may be set as the net doping concentration. A carrier means an electron charge carrier or a hole charge carrier. The carrier concentration measured by the CV method or the SRP method may be set as a value in a thermal equilibrium state. Furthermore, in a region of an N type, the donor concentration is sufficiently higher than the acceptor concentration, and therefore, the carrier concentration in the region may be set as the donor concentration. Similarly, in a region of a P type, the carrier concentration in the region may be set as the acceptor concentration. In the present specification, the doping concentration of the N type region may be referred to as the donor concentration, and the doping concentration of the P type region may be referred to as the acceptor concentration.

Furthermore, when a concentration distribution of the donor, acceptor, or net doping has a peak, a value of the peak may be set as the concentration of the donor, acceptor, or net doping in the region. When the concentration of the donor, acceptor, or net doping is approximately uniform in a region, or the like, an average value of the concentration of the donor, acceptor, or net doping in the region may be set as the concentration of the donor, acceptor, or net doping.

The carrier concentration measured by the SRP method may be lower than the concentration of the donor or the acceptor. In a range where a current flows when a spreading resistance is measured, the carrier mobility of the semiconductor substrate may be lower than a value of that in a crystalline state. The fall in carrier mobility occurs when carriers are scattered due to disorder (disorder) of a crystal structure due to a lattice defect or the like. The carrier concentration becomes lower for the following reason. In the SRP method, a spreading resistance is measured, and a carrier concentration is converted from a measurement value of the spreading resistance. At this time, mobility of the crystalline state is used as the carrier mobility. Meanwhile, despite the fact that carrier mobility is reduced at a position where the lattice defect is introduced, the carrier concentration is calculated by using the carrier mobility of the crystalline state. Therefore, a value smaller than the actual carrier concentration, that is, the donor or acceptor concentration is obtained.

The concentration of the donor or the acceptor calculated from the carrier concentration measured by the CV method or the SRP method may be lower than a chemical concentration of an element representing the donor or the acceptor. As an example, in a silicon semiconductor, a donor concentration of phosphorus or arsenic serving as a donor or an acceptor concentration of boron (boron) serving as an acceptor is approximately 99% of chemical concentrations of these. On the other hand, in the silicon semiconductor, a donor concentration of hydrogen serving as a donor is approximately 0.1% to 10% of a chemical concentration of hydrogen. In the present specification, an SI unit system is adopted. In the present specification, a unit of a distance or length may be represented by cm (centimeter). In this case, various calculations may be converted into m (meter) to be calculated. Regarding indication of numerical values meaning a power of 10, for example, indication of 1E+16 means 1×10¹⁶, and indication of 1E-16 means 1×10⁻¹⁶.

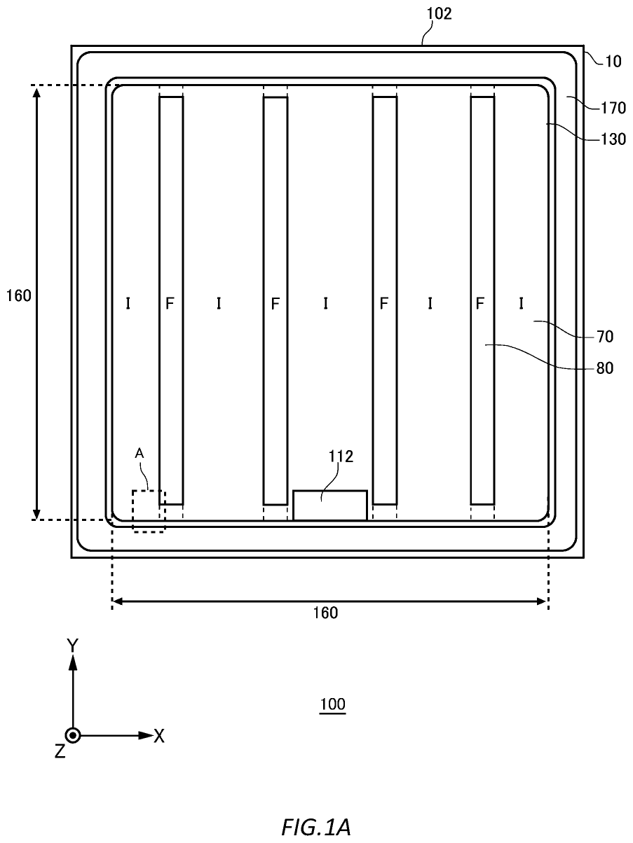

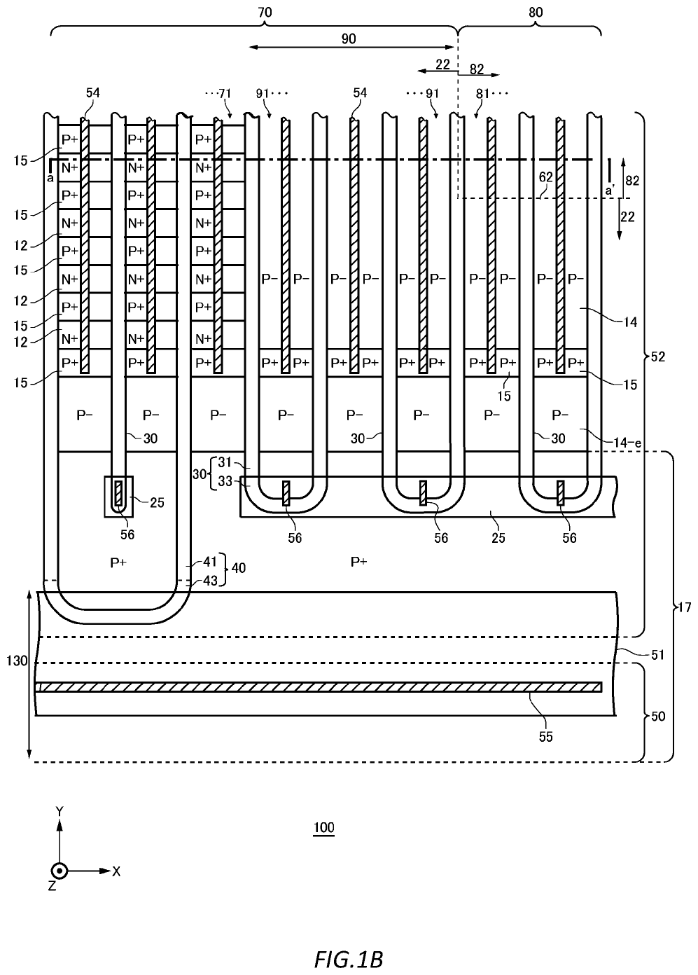

FIG. 1A shows an example of a top view of a semiconductor device 100. FIG. 1A shows a position at which each member is projected on an upper surface of a semiconductor substrate 10. FIG. 1A shows merely some members of the semiconductor device 100, and omits some members. The semiconductor device 100 is a semiconductor chip including a transistor portion 70 and a diode portion 80.

The transistor portion 70 includes a transistor such as an IGBT (Insulated Gate Bipolar Transistor). The diode portion 80 includes a diode such as a free wheel diode (FWD). The semiconductor device 100 of the present example is a reverse conducting IGBT (RC-IGBT) having a transistor portion 70 and a diode portion 80 on the same chip.

The semiconductor substrate 10 is a substrate that is formed of a semiconductor material. The semiconductor substrate 10 may be a silicon substrate, a silicon carbide substrate, or a nitride semiconductor substrate or the like such as a gallium nitride semiconductor substrate. The semiconductor substrate 10 in the present example is a silicon substrate. The semiconductor substrate 10 may be a wafer cut out from a semiconductor ingot, or may be a chip obtained by singulating the wafer. The semiconductor ingot may be manufactured by any of a Chokralsky method (CZ method), a magnetic field applied Chokralsky method (MCZ method), or a float zone method (FZ method).

The semiconductor substrate 10 has end sides 102 in a top view. When merely referred to as the top view in the present specification, it means that the semiconductor substrate 10 is viewed from an upper surface side. The semiconductor substrate 10 of the present example includes two sets of end sides 102 facing each other in the top view. In FIG. 1A, the X axis and the Y axis are parallel to any of the end sides 102. In addition, the Z axis is perpendicular to the upper surface of the semiconductor substrate 10. The semiconductor substrate 10 includes an active portion 160 and an edge termination structure portion 170.

The active portion 160 is a region where a main current flows in the depth direction between the upper surface and a lower surface of the semiconductor substrate 10 when the semiconductor device 100 operates. An emitter electrode is provided above the active portion 160, but is omitted in FIG. 1A.

The active portion 160 is provided with at least one of the transistor portion 70 including a transistor element such as an IGBT, or the diode portion 80 including a diode element such as a free wheel diode (FWD). In the example of FIG. 1A, the transistor portion 70 and the diode portion 80 are alternately arranged along a predetermined array direction (the X axis direction in the present example) on the upper surface of the semiconductor substrate 10. The active portion 160 in another example may be provided with only one of the transistor portion 70 or the diode portion 80.

In FIG. 1A, a region where the transistor portion 70 is arranged is denoted by a symbol “I”, and a region where the diode portion 80 is arranged is denoted by a symbol F. In the present specification, a direction perpendicular to the array direction in the top view may be referred to as an extending direction (the Y axis direction in FIG. 1A). Each of the transistor portions 70 and the diode portions 80 may have a longitudinal length in the extending direction. In other words, the length of each of the transistor portions 70 in the Y axis direction is larger than the width in the X axis direction. Similarly, the length of each of the diode portions 80 in the Y axis direction is larger than the width in the X axis direction. The extending direction of the transistor portion 70 and the diode portion 80, and the longitudinal direction of each trench portion described below may be the same.

Each of the diode portions 80 includes a cathode region of an N+ type in a region in contact with the lower surface of the semiconductor substrate 10. In the present specification, a region where the cathode region is provided is referred to as the diode portion 80. In other words, the diode portion 80 is a region that overlaps with the cathode region in the top view. On the lower surface of the semiconductor substrate 10, a collector region of a P+ type may be provided in a region other than the cathode region.

The transistor portion 70 includes the collector region of the P+ type in a region in contact with the lower surface of the semiconductor substrate 10. In addition, in the transistor portion 70, there is periodically arranged a gate structure which includes an N type emitter region, a P type base region, a gate conductive portion, and a gate dielectric film, on the upper surface side of the semiconductor substrate 10.

The semiconductor device 100 may have one or more pads above the semiconductor substrate 10. The semiconductor device 100 of the present example has a gate pad 112. The semiconductor device 100 may have a pad such as an anode pad, a cathode pad, and a current detection pad. Each pad is arranged in the vicinity of the end side 102. The vicinity of the end side 102 refers to a region between the end side 102 and the emitter electrode in the top view. When the semiconductor device 100 is mounted, each pad may be connected to an external circuit via a wiring such as a wire.

A gate potential is applied to the gate pad 112. The gate pad 112 is electrically connected to the conductive portion of the gate trench portion of the active portion 160. The semiconductor device 100 includes a gate runner 130 that connects the gate pad 112 and the gate trench portion.

The gate runner 130 is electrically connected to the gate conductive portion of the transistor portion 70 and applies a gate voltage to the transistor portion 70. The gate runner 130 is provided so as to enclose an outer circumference of the active portion 160 in the top view. The gate runner 130 is electrically connected to the gate pad 112 provided in the edge termination structure portion 170. The gate runner 130 may be provided between the transistor portion 70 and the diode portion 80 in the top view.

Further, the semiconductor device 100 may include a temperature sensing portion (not shown) that is a PN junction diode formed of polysilicon or the like, and a current detection portion (not shown) that simulates an operation of the transistor portion provided in the active portion 160.

The semiconductor device 100 of the present example includes the edge termination structure portion 170 between the active portion 160 and the end side 102 in the top view. The edge termination structure portion 170 of the present example is arranged between the gate runner 130 and the end side 102. The edge termination structure portion 170 reduces an electric field strength on the upper surface side of the semiconductor substrate 10. The edge termination structure portion 170 may include at least one of a guard ring, a field plate, or a RESURF which is annularly provided to enclose the active portion 160.

FIG. 1B is an enlarged view of a region A in FIG. 1A. The region A is a region including the transistor portion 70, the diode portion 80, and the gate runner 130. The gate runner 130 of the present example includes a gate metal layer 50 and a gate runner portion 51.

A boundary region 90 is provided between the transistor portion 70 and the diode portion 80 on the front surface of the semiconductor substrate 10. The front surface 21 of the semiconductor substrate 10 refers to one of the two principal surfaces opposite to each other in the semiconductor substrate 10. The front surface 21 will be described below.

The semiconductor device 100 of the present example includes a gate trench portion 40, a dummy trench portion 30, a well region 17, an emitter region 12, a base region 14, and a contact region 15 that are formed inside the front surface 21 side of the semiconductor substrate 10. In addition, the semiconductor device 100 of the present example includes an emitter electrode 52 and a gate metal layer 50 provided above the front surface 21 of the semiconductor substrate 10. The emitter electrode 52 and the gate metal layer 50 are provided separate from each other.

An interlayer dielectric film is formed between the emitter electrode 52 and the gate metal layer 50, and the front surface 21 of the semiconductor substrate 10, but the interlayer dielectric film is omitted in FIG. 18. In the interlayer dielectric film of the present example, a contact hole 54, a contact hole 55, and a contact hole 56 are formed to penetrate through the interlayer dielectric film.

The emitter electrode 52 is electrically connected to the emitter region 12, the contact region 15, and the base region 14 on the front surface 21 of the semiconductor substrate 10 via the contact hole 54 formed in the interlayer dielectric film. Also, the emitter electrode 52 is connected to the dummy conductive portion of the dummy trench portion 30 via the contact hole 56. Between the emitter electrode 52 and the dummy conductive portion, a connection portion 25 formed of a conductive material such as polysilicon doped with impurities may be provided.

The gate metal layer 50 is in contact with the gate runner portion 51 via the contact hole 55. The gate runner portion 51 is formed of a semiconductor such as polysilicon doped with impurities. The gate runner portion 51 is connected to a gate conductive portion in the gate trench portion 40 on the front surface of the semiconductor substrate 10.

The emitter electrode 52 and the gate metal layer 50 are formed of a material including metal. For example, at least a partial region of each electrode may be formed of metal such as aluminum (Al) or a metal alloy such as an aluminum-silicon alloy (AlSi) and an aluminum-silicon-copper alloy (AlSiCu). Each electrode may have, in an under layer of the region formed of aluminum or the like, barrier metal which is formed of titanium, titanium compounds, or the like. Further, each electrode may include a plug, which is formed by embedding tungsten or the like so as to be in contact with the barrier metal and aluminum or the like, in the contact hole.

The well region 17 is provided so as to overlap with the gate metal layer 50 and the gate runner portion 51. The well region 17 is provided to extend at a predetermined width also in a range not overlapping with the gate metal layer 50 and the gate runner portion 51. The well region 17 of the present example is provided apart from an end of the contact hole 54 in the Y axis direction toward the gate metal layer 50. The well region 17 is a region of a second conductivity type in which the doping concentration is higher than that of the base region 14. The base region 14 of the present example is of the P− type, and the well region 17 is of the P+ type.

Each of the transistor portion 70 and the diode portion 80 includes a plurality of trench portions arrayed in an array direction on the front surface 21 of the semiconductor substrate 10. In the transistor portion 70 of the present example, one or more gate trench portions 40 and one or more dummy trench portions 30 are alternately provided along the array direction. In the diode portion 80 of the present example, the plurality of dummy trench portions 30 are provided along the array direction. In the diode portion 80 of the present example, the gate trench portion 40 is not provided.

In the transistor portion 70, one or more gate trench portions 40 are arrayed at a predetermined interval along the array direction of each trench. The gate conductive portion inside the gate trench portion 40 is electrically connected to the gate metal layer 50 to be applied by a gate potential. In the transistor portion 70, one or more dummy trench portions 30 may be arrayed at a predetermined interval along the array direction. A potential different from the gate potential is applied to the dummy conductive portion inside the dummy trench portion 30. The dummy conductive portion of the present example is electrically connected to the emitter electrode 52 to be applied by an emitter potential.

In the transistor portion 70, one or more gate trench portions 40 and one or more dummy trench portions 30 may be formed alternately along the array direction. Also, the dummy trench portions 30 are arrayed in the diode portion 80 and the boundary region 90 at a predetermined interval along the array direction. Note that the transistor portion 70 may alternatively be constituted only by the gate trench portion 40 without the dummy trench portion 30 being provided.

The gate trench portion 40 of the present example may have two extending portions 41 extending along the extending direction perpendicular to the array direction (portions of a trench that are linear along the extending direction), and a connecting portion 43 connecting the two extending portions 41. The extending direction in FIG. 1B is the Y axis direction.

Preferably, at least a part of the connecting portion 43 is provided in a curved shape in the top view. By connecting the end portions of the two extending portions 41 in the Y axis direction by the connecting portion 43, an electric field strength at the end portions of the extending portions 41 can be reduced.

In the transistor portion 70, the dummy trench portions 30 are provided between the respective extending portions 41 of the gate trench portions 40. One dummy trench portion 30 may be provided or a plurality of dummy trench portions 30 may be provided between the respective extending portions 41. The dummy trench portion 30 may have a linear shape extending in the extending direction, or may have extending portions 31 and a connecting portion 33 similar to the gate trench portion 40. The semiconductor device 100 shown in FIG. 1B includes both the linear dummy trench portion 30 not having the connecting portion 33 and the dummy trench portion 30 having the connecting portion 33. A direction in which the extending portions 41 of the gate trench portion 40 or the extending portions 31 of the dummy trench portion 30 extend to be long in the extending direction is referred to as a longitudinal direction of the trench portion. The longitudinal direction of the gate trench portion 40 or the dummy trench portion 30 may match with the extending direction. In the present example, the extending direction and the longitudinal direction are the Y axis direction. The array direction in which the plurality of gate trench portions 40 or dummy trench portions 30 are arrayed is referred to as a lateral direction of the trench portion. The lateral direction may match with the array direction. The lateral direction may also be perpendicular to the longitudinal direction. In the present example, the lateral direction is perpendicular to the longitudinal direction. In the present example, the array direction and the lateral direction are the X axis direction.

In the connecting portion 43 at an edge of the gate trench portion 40, the gate conductive portion inside the gate trench portion 40 is connected to the gate runner portion 51. The gate trench portion 40 may be provided protrusively from the dummy trench portion 30 toward the gate runner portion 51 side in the extending direction (the Y axis direction). The protruding portion of the gate trench portion 40 is connected to the gate runner portion 51.

A diffusion depth of the well region 17 may be deeper than the depth of the gate trench portion 40 and the dummy trench portion 30. The end portions of the gate trench portion 40 and the dummy trench portion 30 in the Y axis direction are provided in the well region 17 in a top view. In other words, the bottom in the depth direction of each trench portion is covered with the well region 17 at the end portion of each trench portion in the Y axis direction. With this configuration, the electric field strength in the bottom of each trench portion can be reduced.

A mesa portion is provided between the respective trench portions in the array direction. The mesa portion refers to a region sandwiched between the trench portions inside the semiconductor substrate 10. As an example, an upper end of the mesa portion is the upper surface of the semiconductor substrate 10. The depth position of the lower end of the mesa portion is the same as the depth position of the lower end of the trench portion. The mesa portion of the present example is provided extending in the extending direction (the Y axis direction) along the trench portion, on the upper surface of the semiconductor substrate 10.

The boundary region 90 is provided in direct contact with the diode portion 80 in the transistor portion 70. The boundary region 90 is a region where the emitter region 12 of the first conductivity type is not provided in the mesa portion on the front surface side of the semiconductor substrate 10, and where the collector region 22 is provided on the back surface side of the semiconductor substrate 10. The boundary region 90 may include the base region 14 on the front surface 21. Note that in FIG. 1B, regarding the cathode region 82 provided on the back surface side of the semiconductor substrate 10, a position thereof when projected on the front surface side is shown. The boundary region 90 is provided with the dummy trench portion 30.

The mesa portion 71, the mesa portion 81, and the mesa portion 91 are mesa portions respectively provided in the transistor portion 70, the diode portion 80, and the boundary region 90. When merely referred to as the mesa portion in the present specification, it indicates each of the mesa portion 71, the mesa portion 81, and the mesa portion 91. The mesa portion is a portion of the semiconductor substrate 10 interposed between two trench portions adjacent to each other, and may be a portion ranging from the front surface 21 of the semiconductor substrate 10 to the depth of the lowermost bottom portion of each trench portion. The extending portions of each trench portion may be regarded as one trench portion. That is, the region sandwiched between two extending portions may be set to be a mesa portion.

Each mesa portion is provided with the base region 14. Of the base regions 14 exposed on the upper surface of the semiconductor substrate 10 in the mesa portion, the region arranged closest to the gate metal layer 50 is referred to as a base region 14-e. While FIG. 1B shows the base region 14-e arranged at one end portion of each mesa portion in the extending direction, the base region 14-e is also arranged at the other end portion of each mesa portion. In each mesa portion, at least one of the emitter region 12 of the first conductivity type or the contact region 15 of the second conductivity type may be provided in a region sandwiched between the base regions 14-e in a top view. The emitter region 12 of the present example is of an N+ type, and the contact region 15 is of a P+ type. The emitter region 12 and the contact region 15 may be provided between the base region 14 and the upper surface of the semiconductor substrate 10 in the depth direction.

The mesa portion 71 of the transistor portion 70 includes the emitter region 12 exposed on the upper surface of the semiconductor substrate 10. The emitter region 12 is provided in contact with the gate trench portion 40. The mesa portion 71 in contact with the gate trench portion 40 may be provided with the contact region 15 exposed on the upper surface of the semiconductor substrate 10.

Each of the contact region 15 and the emitter region 12 in the mesa portion 71 is provided from one trench portion to the other trench portion in the X axis direction. As an example, the contact region 15 and the emitter region 12 in the mesa portion 71 are alternately arranged along the extending direction of the trench portion (the Y axis direction).

In another example, the contact region 15 and the emitter region 12 in the mesa portion 71 may be provided in a stripe shape along the extending direction of the trench portion (the Y axis direction). For example, the emitter region 12 is provided in a region in contact with the trench portion, and the contact region 15 is provided in a region sandwiched between the emitter regions 12.

The emitter region 12 is not provided in the mesa portion 81 of the diode portion 80. The base region 14 and the contact region 15 may be provided on an upper surface of the mesa portion 81. The contact region 15 may be provided in contact with each of the base regions 14-e in a region sandwiched between the base regions 14-e on the upper surface of the mesa portion 81. The base region 14 may be provided in a region sandwiched between the contact regions 15 on the upper surface of the mesa portion 81. The base region 14 may be arranged in an entire region sandwiched between the contact regions 15.

The contact hole 54 is provided above each mesa portion. The contact hole 54 is arranged in the region sandwiched between the base regions 14-e. The contact hole 54 of the present example is provided above each region of the contact region 15, the base region 14, and the emitter region 12. The contact hole 54 is not provided in regions corresponding to the base region 14-e and the well region 17. The contact hole 54 may be arranged at the center of the mesa portion 71 in the array direction (the X axis direction).

In the diode portion 80, an N+ type cathode region 82 is provided in a region adjacent to the lower surface of the semiconductor substrate 10. The doping concentration of the cathode region 82 is higher than the doping concentration of the drift region 18. On the lower surface of the semiconductor substrate 10, a P+ type collector region 22 may be provided in a region where the cathode region 82 is not provided. The cathode region 82 and the collector region 22 are provided between the back surface 23 of the semiconductor substrate 10 and the buffer region 20. In FIG. 1B, a boundary 62 between the cathode region 82 and the collector region 22 is indicated by a dotted line.

The cathode region 82 is arranged apart from the well region 17 in the Y axis direction. With this configuration, it is possible to secure a distance between the P type region (the well region 17) that has a relatively high doping concentration and is formed to a deep position and the cathode region 82, improve a breakdown voltage, and suppress implantation of holes from the well region 17. In the present example, an end portion of the cathode region 82 in the Y axis direction is arranged farther away from the well region 17 than an end portion of the contact hole 54 in the Y axis direction. In another example, the end portion of the cathode region 82 in the Y axis direction may be arranged between the well region 17 and the contact hole 54.

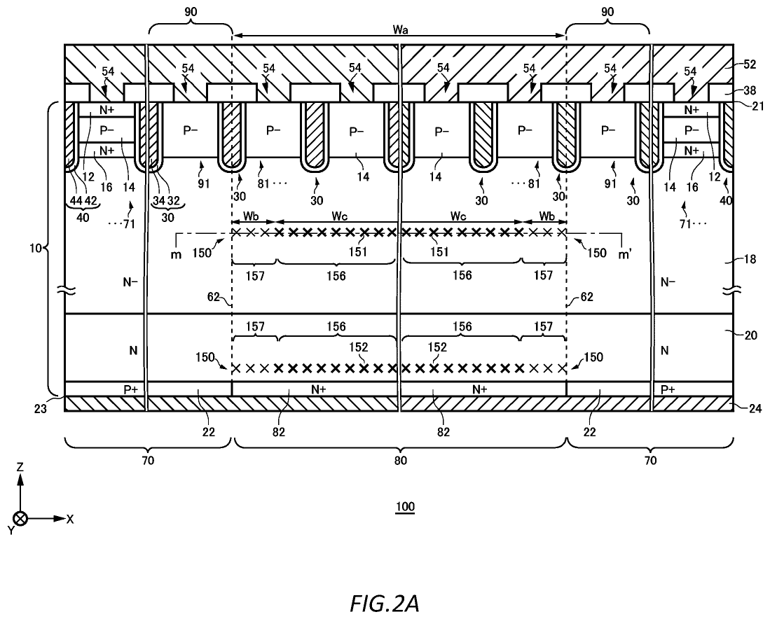

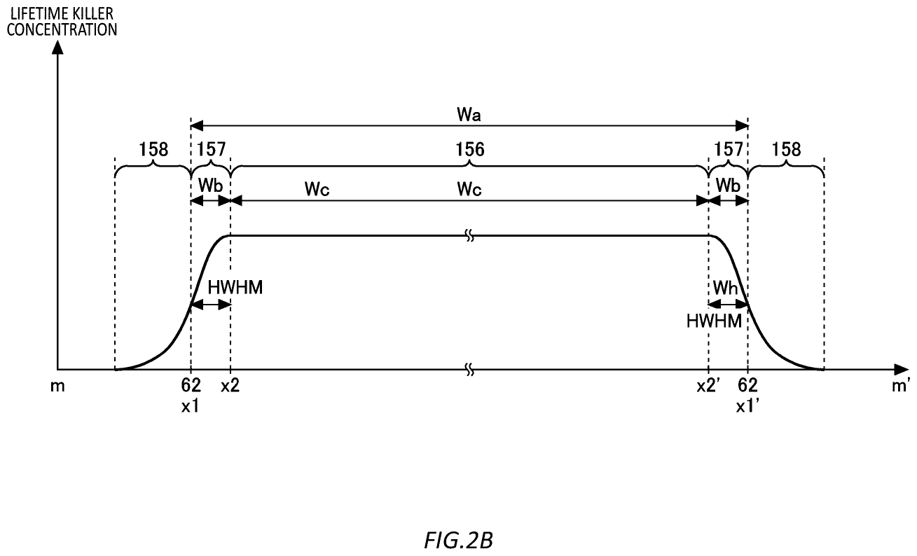

FIG. 2A is a diagram showing an example of an XZ cross section including a cross section a-a′ in FIG. 1B. The XZ cross section including the cross section a-a′ is an XZ plane that passes through the emitter region 12 in the transistor portion 70. The semiconductor device 100 in the present example has the semiconductor substrate 10, the interlayer dielectric film 38, the emitter electrode 52, and the collector electrode 24 in the XZ cross section including the cross section a-a′. The emitter electrode 52 is formed above the semiconductor substrate 10 and the interlayer dielectric film 38.

The drift region 18 is a region of the first conductivity type, which is provided in the semiconductor substrate 10. The drift region 18 in the present example is of the N− type as an example. The drift region 18 may be a region that has remained without other doping regions being formed in the semiconductor substrate 10. That is, the doping concentration of the drift region 18 may be a doping concentration of the semiconductor substrate 10.

The buffer region 20 is a region of the first conductivity type, which is provided below the drift region 18. The buffer region 20 of the present example is provided closer to the back surface 23 of the semiconductor substrate 10 than a center of the semiconductor substrate 10 in the depth direction. The buffer region 20 in the present example is of the N type as an example. The doping concentration of the buffer region 20 is higher than the doping concentration of the drift region 18. The buffer region 20 may function as a field-stop layer which prevents a depletion layer expanding from the lower surface side of the base region 14 from reaching the collector region 22 of the second conductivity type and the cathode region 82 of the first conductivity type.

The collector region 22 and the cathode region 82 are provided on the back surface 23 of the semiconductor substrate 10. The collector region 22 is provided below the buffer region 20 in the transistor portion 70. The cathode region 82 is provided below the buffer region 20 in the diode portion 80. The boundary 62 between the collector region 22 and the cathode region 82 may be a boundary between the transistor portion 70 and the diode portion 80.

The collector electrode 24 is formed on the back surface 23 of the semiconductor substrate 10. The collector electrode 24 is formed of a conductive material such as metal.

For example, at least a partial region of the collector electrode 24 may be formed of metal such as aluminum (Al) or a metal alloy such as an aluminum-silicon alloy (AlSi) and an aluminum-silicon-copper alloy (AlSiCu).

The base region 14 is a region of the second conductivity type, which is provided above the drift region 18 in the mesa portion 71, the mesa portion 91, and the mesa portion 81. The base region 14 is provided in contact with the gate trench portion 40. The base region 14 may be provided in contact with the dummy trench portion 30.

The emitter region 12 is provided between the base region 14 and the front surface 21 in the mesa portion 71. The emitter region 12 is provided in contact with the gate trench portion 40. The emitter region 12 may or may not be in contact with the dummy trench portion 30. Note that the emitter region 12 may not be provided in the mesa portion 91.

The contact region 15 is provided above the base region 14 in the mesa portion 91. The contact region 15 is provided in contact with the gate trench portion 40 in the mesa portion 91. In another cross section, the contact region 15 may be provided on the front surface 21 in the mesa portion 71.

The accumulation region 16 is a region of the first conductivity type, which is provided closer to the front surface 21 of the semiconductor substrate 10 than the drift region 18. The accumulation region 16 in the present example is of the N+ type as an example. The accumulation region 16 is provided in the mesa portion 71. The accumulation region 16 may also be provided in the mesa portion 81 and the mesa portion 91.

In addition, the accumulation region 16 is provided in contact with the gate trench portion 40. The accumulation region 16 may or may not be in contact with the dummy trench portion 30. The doping concentration of the accumulation region 16 is higher than the doping concentration of the drift region 18. Providing the accumulation region 16 can enhance the carrier injection enhancement effect (IE effect) to reduce an ON voltage of the transistor portion 70.

One or more gate trench portions 40 and one or more dummy trench portions 30 are provided on the front surface 21. Each trench portion is provided from the front surface 21 to the drift region 18. In a region where at least any of the emitter region 12, the base region 14, the contact region 15, or the accumulation region 16 is provided, each trench portion also penetrates through these regions to reach the drift region 18. The configuration of the trench portion penetrating through the doping region is not limited to that manufactured in the order of forming the doping region and then forming the trench portion. The configuration of the trench portion penetrating through the doping region also includes a configuration of the doping region being formed between the trench portions after forming the trench portion.

The gate trench portion 40 has a gate trench, a gate dielectric film 42, and a gate conductive portion 44 which are formed in the front surface 21. The gate dielectric film 42 is formed to cover an inner wall of the gate trench. The gate dielectric film 42 may be formed by oxidizing or nitriding a semiconductor on the inner wall of the gate trench. The gate dielectric film 42 is formed inside the gate trench, and the gate conductive portion 44 is formed on an inner side of the gate dielectric film 42. The gate dielectric film 42 insulates the gate conductive portion 44 from the semiconductor substrate 10. The gate conductive portion 44 is formed of a conductive material such as polysilicon. The gate trench portion 40 is covered by the interlayer dielectric film 38 on the front surface 21.

The gate conductive portion 44 includes a region opposing the adjacent base region 14 on the mesa portion 71 side with the gate dielectric film 42 interposed therebetween in a depth direction of the semiconductor substrate 10. When a predetermined voltage is applied to the gate conductive portion 44, a channel is formed to a surface layer being at a boundary within the base region 14 and in direct contact with the gate trench, due to an electron inversion layer.

The dummy trench portion 30 may have the same structure as the gate trench portion 40. The dummy trench portion 30 has a dummy trench, a dummy dielectric film 32, and a dummy conductive portion 34 which are formed in the front surface 21 side. The dummy dielectric film 32 is formed to cover the inner wall of the dummy trench. The dummy conductive portion 34 is formed inside the dummy trench and also formed on the inner side of the dummy dielectric film 32. The dummy dielectric film 32 insulates the dummy conductive portion 34 from the semiconductor substrate 10. The dummy trench portion 30 is covered by the interlayer dielectric film 38 in the front surface 21.

The interlayer dielectric film 38 is provided at the front surface 21. The emitter electrode 52 is provided above the interlayer dielectric film 38. In the interlayer dielectric film 38, one or more contact holes 54 are provided for electrically connecting the emitter electrode 52 to the semiconductor substrate 10. Similarly, the contact hole 55 and the contact hole 56 may be provided to penetrate through the interlayer dielectric film 38.

The lifetime control portion 150 is provided in the semiconductor substrate 10 and contains a lifetime killer. The lifetime control portion 150 may be a region where a lifetime killer is intentionally formed by implanting an impurity into the semiconductor substrate 10, or the like. In one example, the lifetime control portion 150 is formed by implanting helium into the semiconductor substrate 10. By providing the lifetime control portion 150, a turn-off time is reduced and a tail current is suppressed, and thus losses during switching can be reduced.

The lifetime killer is a recombination center of carriers. The lifetime killer may be a lattice defect. For example, the lifetime killer may be a vacancy, a divacancy, a defect complex of these with elements configuring the semiconductor substrate 10, or dislocation. Furthermore, the lifetime killer may be a noble gas element such as helium and neon, a metal element such as platinum, or the like. The lifetime killer may be a recombination center formed closer to an implantation surface of the semiconductor substrate 10 than hydrogen that has stopped, after hydrogen ions are implanted into the implantation surface. An electron beam may be used for forming the lattice defect. An impurity dose amount for forming the lifetime control portion 150 may be 0.5 E10 cm⁻² or more and 1.0 E13 cm⁻² or less, or may be 5.0 E10 cm⁻² or more and 5.0 E11 cm⁻² or less. Acceleration energy for forming the lifetime control portion 150 may be 100 keV or more and 100 MeV or less.

A lifetime killer concentration is a concentration at the recombination center of carriers. The lifetime killer concentration may be a concentration of the lattice defect. For example, the lifetime killer concentration may be a vacancy concentration of a vacancy, a divacancy, or the like, may be a defect complex concentration of these vacancies with elements configuring the semiconductor substrate 10, or may be a dislocation concentration. Alternatively, the lifetime killer concentration may be a chemical concentration of the noble gas element such as helium and neon, or may be a chemical concentration of the metal element such as platinum.

The lifetime control portion 150 includes at least one of a front surface side lifetime control region 151 or a back surface side lifetime control region 152. The lifetime control portion 150 includes a main region 156 and a decay region 157.

The front surface side lifetime control region 151 is provided closer to the front surface 21 than the center of the semiconductor substrate 10 in the depth direction. The front surface side lifetime control region 151 may include the main region 156 and the decay region 157.

The back surface side lifetime control region 152 is provided closer to the back surface 23 than the center of the semiconductor substrate 10 in the depth direction. The back surface side lifetime control region 152 of the present example is provided in the buffer region 20. The back surface side lifetime control region 152 may include the main region 156 and the decay region 157.

The lifetime control portion 150 may be formed by implanting impurity ions for forming a lifetime killer from the back surface 23 side. The impurity ions for forming a lifetime killer may simply be referred to as the impurity ions. The impurity ions are, for example, helium ions. With this configuration, an effect on the front surface 21 side of the semiconductor device 100 can be avoided. For example, the lifetime control portion 150 is formed by implanting helium ions from the back surface 23 side. Herein, which of the front surface 21 side and the back surface 23 side the implantation is performed from for forming the lifetime control portion 150 can be determined by acquiring a state on the front surface 21 side by the SRP method or a measurement of a leak current.

The method of forming the front surface side lifetime control region 151 and that of the back surface side lifetime control region 152 may be the same or may differ. Both of the front surface side lifetime control region 151 and the back surface side lifetime control region 152 may be formed by implanting impurity ions from the back surface 23 side. The front surface side lifetime control region 151 may be formed by implanting impurity ions from the front surface 21 side, and the back surface side lifetime control region 152 may be formed by implanting impurity ions from the back surface 23 side. Both of the front surface side lifetime control region 151 and the back surface side lifetime control region 152 may be formed by implanting impurity ions from the front surface 21 side. The impurity ion dose amounts when respectively forming the front surface side lifetime control region 151 and the back surface side lifetime control region 152 may be the same or may differ.

The main region 156 is provided in the diode portion 80. The main region 156 may be a region obtained by directly implanting impurity ions. For example, when forming the lifetime control portion 150 using a mask, the main region 156 is a region not covered by the mask. The main region 156 of the front surface side lifetime control region 151 and that of the back surface side lifetime control region 152 may be provided in the same region in a top view, or may be provided in different regions.

The decay region 157 is provided to extend from the main region 156 in a direction parallel to the front surface 21 of the semiconductor substrate 10. The decay region 157 is a region where the lifetime killer concentration has decayed more than in the main region 156. The decay region 157 may be a region formed by a thermal diffusion of the implanted impurity instead of the region implanted with the impurity ions. The decay region 157 of the front surface side lifetime control region 151 and that of the back surface side lifetime control region 152 may be provided in the same region in a top view, or may be provided in different regions.

The decay region 157 of the present example is provided to extend from the main region 156 in the direction parallel to the front surface 21 of the semiconductor substrate 10 in the diode portion 80. That is, the diode portion 80 includes the main region 156 and the decay region 157. The decay region 157 of the present example extends from the main region 156 to the boundary 62 between the collector region 22 and the cathode region 82 in the array direction. The decay region 157 may extend from the main region 156 to the boundary 62 between the collector region 22 and the cathode region 82 in the array direction, and be terminated at the boundary 62.

Herein, a width of the diode portion 80 in the trench array direction is represented by Wa, a width of the decay region 157 in the trench array direction is represented by Wb, and a width of the main region 156 in the trench array direction is represented by Wc. In this case, Wa>Wc may be satisfied, or (Wa−2Wb)>Wc may be satisfied. The width Wc of the main region 156 in the trench array direction may be smaller than the width Wa of the diode portion 80 in the trench array direction. The main region 156 may be formed inside the diode portion 80. Note that the width Wb of the decay region 157 in the trench array direction may be the same as a diffusion half width at half maximum Wh of the lifetime killer for forming the lifetime control portion 150 in the direction parallel to the front surface 21 of the semiconductor substrate 10. The diffusion half width at half maximum Wh will be described below.

The main region 156 may occupy 80% or more of the width of the diode portion 80 in the trench array direction. That is, 0.8 (Wa−2Wb)/Wa<1.0 may be satisfied.

FIG. 2B is an example of a lifetime killer concentration in a cross section m-m′ in FIG. 2A. The cross section m-m′ passes through the front surface side lifetime control region 151 in the X axis direction. The lifetime killer concentration distribution in the main region 156 may be uniform. The decay region 157 is a region where the lifetime killer concentration decays. The lifetime killer concentration distribution in the decay region 157 may be a Gaussian distribution.

Positions x1 and x1′ of end portions of the lifetime control portion 150 are positions at which the lifetime killer concentration of the decay region 157 becomes half of a maximum value or average concentration of the lifetime killer concentration in the main region 156. Positions x2 and x2′ are positions at which the lifetime killer concentration of the main region 156 starts to decay in the horizontal direction (the X axis direction). That is, the positions x2 and x2′ are positions of end portions of the main region 156. The width We of the main region 156 is a distance between the position x2 and the position x2′. The width Wb of the decay region 157 is a distance between the position x1 and the position x2 or a distance between the position x1′ and the position x2′. The width Wb of the decay region 157 is a half width at half maximum (HWHM) of the lifetime killer concentration distribution. The half width at half maximum may be a diffusion half width at half maximum Wh.

In the lifetime killer concentration distribution, a portion having a concentration lower than a concentration at the position x1 or the position x1′ is set as a seeping portion 158. The positions x1 and x1′ of the end portions of the lifetime control portion 150 in the present example each match with the boundary 62. That is, the seeping portion 158 of the lifetime killer concentration distribution may be positioned in the boundary region 90, or may be positioned in the transistor portion 70.

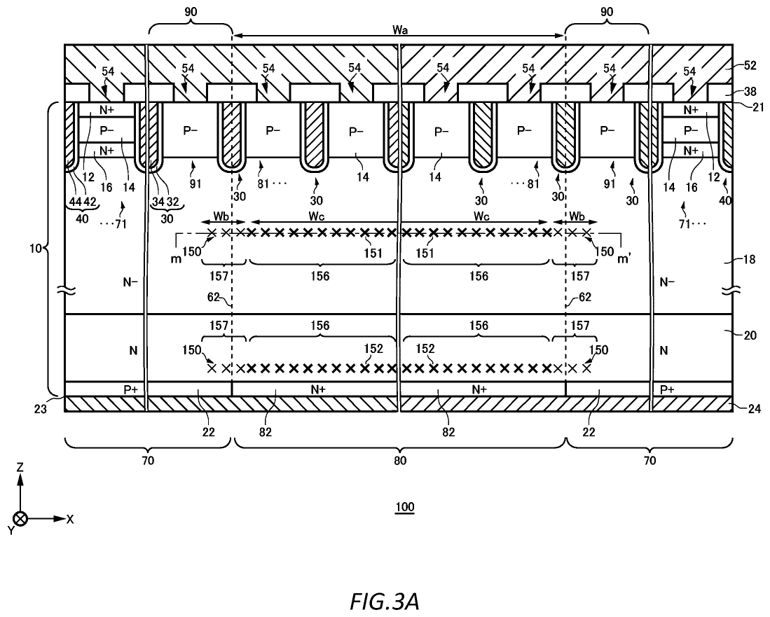

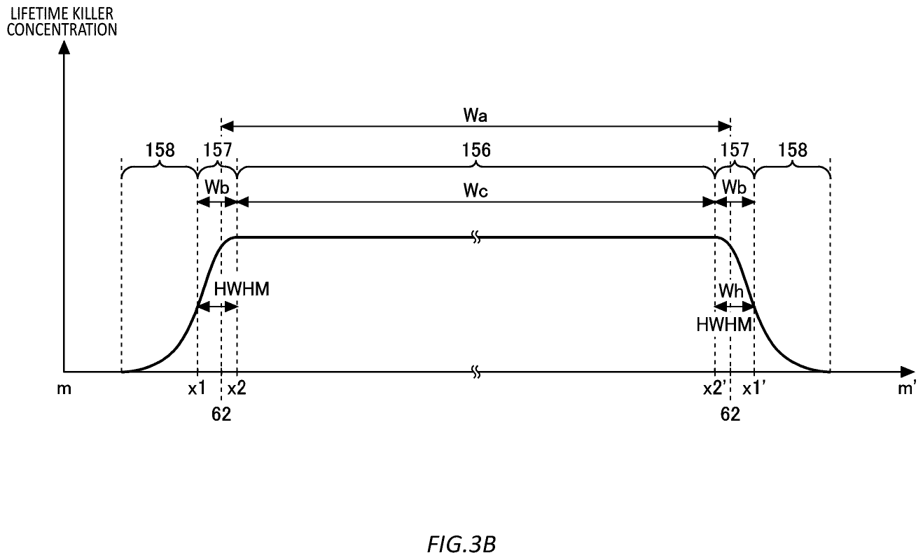

FIG. 3A is an XZ cross section including the cross section a-a′ and shows a modified example of the semiconductor device 100. The semiconductor device 100 of the present example includes the lifetime control portion 150 in a different region from the semiconductor device 100 shown in FIG. 2A. In the present example, differences with the semiconductor device 100 shown in FIG. 2A will be described in particular.

The front surface side lifetime control region 151 and the back surface side lifetime control region 152 are provided in different regions in a top view. The front surface side lifetime control region 151 of the present example includes the main region 156 and the decay region 157. The back surface side lifetime control region 152 does not need to include the decay region 157. The lifetime control portion 150 of the present example may or may not include at least one of the front surface side lifetime control region 151 or the back surface side lifetime control region 152.

The front surface side lifetime control region 151 and the back surface side lifetime control region 152 may be provided in the same region. That is, the main region 156 of the front surface side lifetime control region 151 may be provided in the same region as the main region 156 of the back surface side lifetime control region 152 in the top view. The decay region 157 of the front surface side lifetime control region 151 may be provided in the same region as the decay region 157 of the back surface side lifetime control region 152 in the top view. Note that the front surface side lifetime control region 151 and the back surface side lifetime control region 152 may alternatively be provided in different regions.

The main region 156 is terminated without extending from above the cathode region 82 to the boundary 62 between the collector region 22 and the cathode region 82 in the trench array direction. The decay region 157 extends from the main region 156 to above the collector region 22 beyond the boundary 62 between the collector region 22 and the cathode region 82. The decay region 157 of the present example extends from the main region 156 to an inside of the boundary region 90, but may alternatively extend beyond the boundary region 90. Herein, descriptions are given as the main region 156 and the decay region 157 of the front surface side lifetime control region 151. Note that similarly, the back surface side lifetime control region 152 may also include the main region 156 and the decay region 157 at positions respectively corresponding to the main region 156 and the decay region 157 of the present example.

FIG. 3B is an example of the lifetime killer concentration in the cross section m-m′ in FIG. 3A. In the present example, differences with the semiconductor device 100 shown in FIGS. 2A and 2B will be described in particular. The boundary 62 of the present example is positioned between the position x1 (or x1′) of the end portion of the lifetime control portion 150 and the position x2 (or x2′) of the end portion of the main region 156. In other words, the boundary 62 is positioned in the decay region 157. The seeping portion 158 of the lifetime killer concentration distribution may be positioned apart from the boundary 62 toward an outer side. The seeping portion 158 may be positioned in the boundary region 90, or may be positioned in the transistor portion 70.

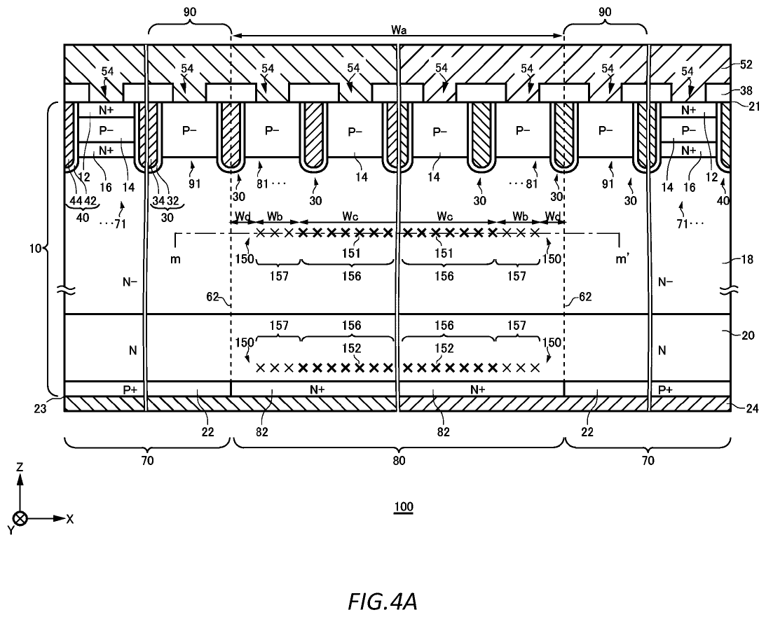

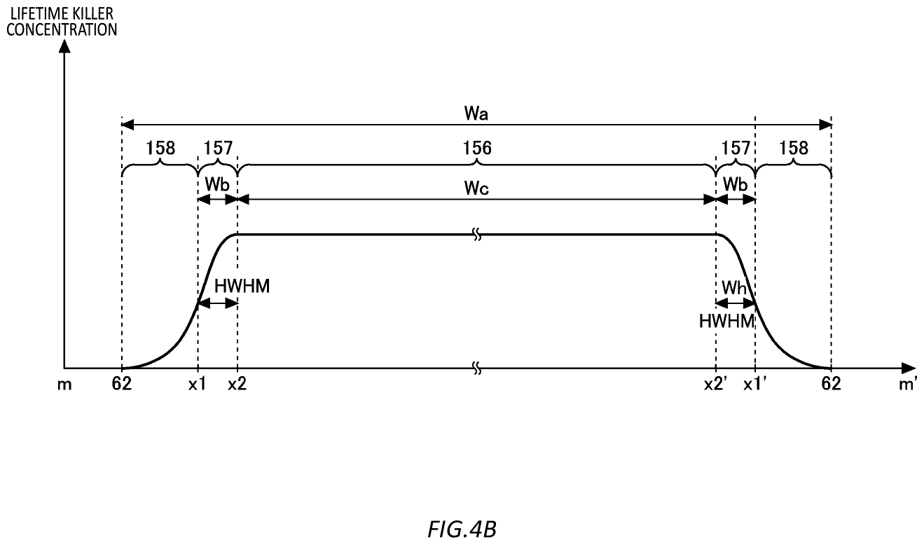

FIG. 4A is an XZ cross section including the cross section a-a′ and shows a modified example of the semiconductor device 100. The semiconductor device 100 of the present example includes the lifetime control portion 150 in a different region from the semiconductor device 100 shown in FIGS. 2A and 3A. In the present example, differences with the semiconductor device 100 shown in FIGS. 2A and 3A will be described in particular.

The lifetime control portion 150 is provided in the diode portion 80, and does not need to be provided in the transistor portion 70. In the present example, both of the front surface side lifetime control region 151 and the back surface side lifetime control region 152 are provided in the diode portion 80 and are not provided in the transistor portion 70. One of the front surface side lifetime control region 151 or the back surface side lifetime control region 152 may be omitted.

The front surface side lifetime control region 151 and the back surface side lifetime control region 152 may be provided in the same region. That is, the main region 156 of the front surface side lifetime control region 151 may be provided in the same region as the main region 156 of the back surface side lifetime control region 152 in the top view. The decay region 157 of the front surface side lifetime control region 151 may be provided in the same region as the decay region 157 of the back surface side lifetime control region 152 in the top view. Note that the front surface side lifetime control region 151 and the back surface side lifetime control region 152 may alternatively be provided in different regions.

The main region 156 extends in the trench array direction above the cathode region 82, and is terminated without extending to the boundary 62 between the collector region 22 and the cathode region 82. The decay region 157 extends from the main region 156 in the trench array direction, and is terminated without extending to the boundary 62 between the collector region 22 and the cathode region 82. That is, the semiconductor device 100 of the present example has a distance Wd between the end portion of the decay region 157 and the boundary 62. The distance Wd of the present example is a distance in the trench array direction, but the distance Wd may also be provided in the trench extending direction. The distance Wd may be smaller than the width Wb, may be the same as the width Wb, or may be larger than the width Wb.

In the present example, the width Wa of the diode portion 80 in the trench array direction may be larger than the width Wc of the main region 156 in the trench array direction. That is, Wa>Wc may be satisfied. Further, the width Wa of the diode portion 80 in the trench array direction may be larger than the width Wc+2Wb of the lifetime control portion 150. That is, Wa>Wc+2Wb may be satisfied.

FIG. 4B is an example of the lifetime killer concentration in the cross section m-m′ in FIG. 4A. In the present example, differences with the semiconductor device 100 shown in FIGS. 3A and 3B will be described in particular. The boundary 62 of the present example is positioned apart from the position x1 (or x1′) of the end portion of the lifetime control portion 150 toward the outer side. The seeping portion 158 of the lifetime killer concentration distribution may be positioned in the diode portion 80. Alternatively, the seeping portion 158 may extend from the inside of the diode portion 80 to the boundary 62. An end portion of the seeping portion 158 may be the boundary 62. The boundary 62 may be positioned more on the outer side toward the transistor side than the position x1 (or x1′).

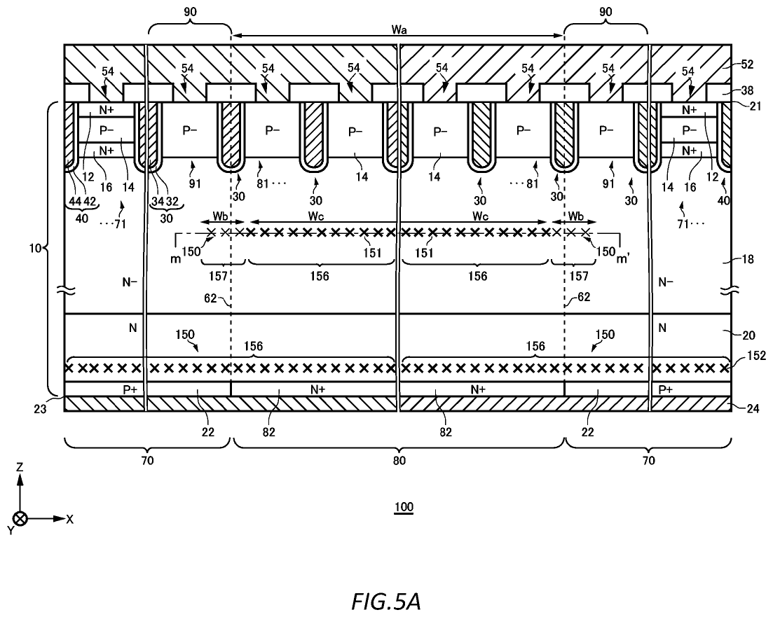

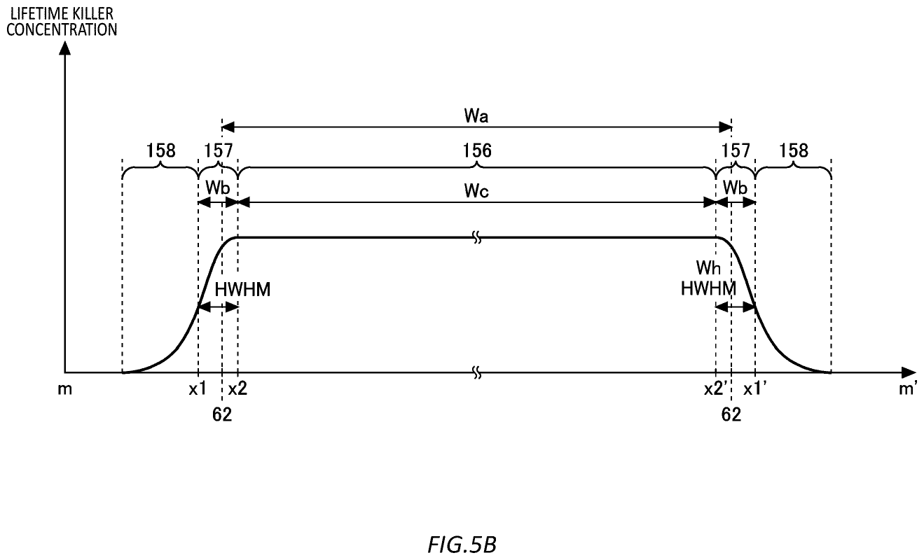

FIG. 5A is an XZ cross section including the cross section a-a′ and shows a modified example of the semiconductor device 100. The semiconductor device 100 of the present example includes the lifetime control portion 150 in a different region from the semiconductor device 100 shown in FIG. 3A. In the present example, differences with the semiconductor device 100 shown in FIG. 3A will be described in particular.

The back surface side lifetime control region 152 of the present example is provided across the entire surface of the semiconductor substrate 10. The back surface side lifetime control region 152 of the present example is provided across the entire surface of the semiconductor substrate 10 in the XY plane, and can be formed without using a mask. Since the back surface side lifetime control region 152 of the present example is formed by implanting an impurity across the entire surface of the back surface 23, the main region 156 is provided across the entire surface of the semiconductor substrate 10. On the other hand, in the case of the present example, the back surface side lifetime control region 152 does not include the decay region 157.

The front surface side lifetime control region 151 is provided in a different region from the back surface side lifetime control region 152 in the top view. The front surface side lifetime control region 151 of the present example includes the main region 156 and the decay region 157.

The main region 156 is terminated without extending from above the cathode region 82 to the boundary 62 between the collector region 22 and the cathode region 82 in the trench array direction. The decay region 157 of the present example extends from the main region 156 to above the collector region 22 beyond the boundary 62 between the collector region 22 and the cathode region 82. As in the other examples, the decay region 157 may be terminated without extending beyond the boundary 62 between the collector region 22 and the cathode region 82, or may be terminated at the boundary 62 between the collector region 22 and the cathode region 82.

Note that the front surface side lifetime control region 151 and the back surface side lifetime control region 152 are not limited to the examples described above. For example, the front surface side lifetime control region 151 may be the example shown in FIG. 2A, and the back surface side lifetime control region 152 may be the example shown in FIG. 3A or the example shown in FIG. 4A. Alternatively, the front surface side lifetime control region 151 may be the example shown in FIG. 3A, and the back surface side lifetime control region 152 may be the example shown in FIG. 2A or the example shown in FIG. 4A. Alternatively, the front surface side lifetime control region 151 may be the example shown in FIG. 4A, and the back surface side lifetime control region 152 may be the example shown in FIG. 2A or the example shown in FIG. 3A.

FIG. 5B is an example of the lifetime killer concentration in the cross section m-m′ in FIG. 5A. FIG. 5B is the same as FIG. 3B.

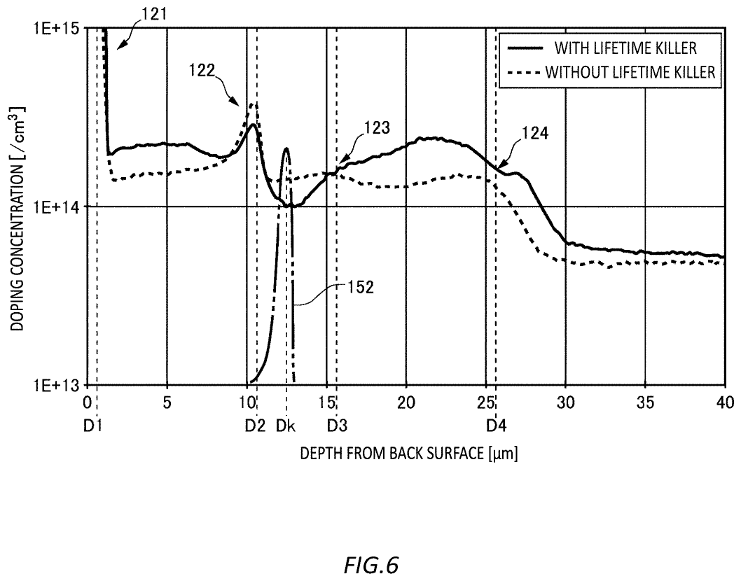

FIG. 6 shows an example of the doping concentration distribution of the buffer region 20. The back surface side lifetime control region 152 of the present example is formed by implanting helium ions, but the method of forming the back surface side lifetime control region 152 is not limited to this. Herein, an effect of forming the back surface side lifetime control region 152, on the buffer region 20 will be described.

The solid line indicates the doping concentration distribution of the buffer region 20 in a case where the back surface side lifetime control region 152 is provided. The broken line indicates the doping concentration distribution of the buffer region 20 in a case where the back surface side lifetime control region 152 is not provided.

The buffer region 20 has one or more peaks of the doping concentration in the depth direction of the semiconductor substrate 10. The buffer region 20 of the present example has four peaks of the doping concentration in the depth direction of the semiconductor substrate 10. The buffer region 20 has the peaks in the stated order of a first peak 121, a second peak 122, a third peak 123, and a fourth peak 124 from the back surface 23 in the depth direction of the semiconductor substrate 10. Depth positions D1 to D4 respectively indicate distances of the first peak 121 to the fourth peak 124 from the back surface 23 in the depth direction. The buffer region 20 may be formed by implanting hydrogen ions. That is, the buffer region 20 may contain a hydrogen donor. The semiconductor substrate 10 of the present example is formed by using the MCZ method, but the present invention is not limited to this.

The chain double-dashed line indicates the lifetime killer concentration when forming the back surface side lifetime control region 152. A depth position Dk indicates a distance between the back surface 23 and a peak of the back surface side lifetime control region 152 in the depth direction of the semiconductor substrate 10. The back surface side lifetime control region 152 may be provided between the second peak 122 and the third peak 123 in the depth direction of the semiconductor substrate 10. That is, the depth position Dk of the back surface side lifetime control region 152 from the back surface 23 may be larger than a depth position D2 of the second peak 122 from the back surface 23 and smaller than a depth position D3 of the third peak 123 from the back surface 23. The back surface side lifetime control region 152 of the present example has a peak of the lifetime killer concentration at a position that is 10 μm or more and 15 μm or less from the back surface 23 of the semiconductor substrate 10 in the depth direction of the semiconductor substrate 10.

The depth position Dk of the back surface side lifetime control region 152 from the back surface 23 may be deeper than a peak formed at a shallowest position from the back surface 23 in the buffer region 20. That is, the depth position Dk may be larger than the depth position D1. The depth position Dk of the back surface side lifetime control region 152 from the back surface 23 may be shallower than a peak formed at a deepest position from the back surface 23 in the buffer region 20. That is, when the buffer region 20 has four peaks as in the present example, the depth position Dk may be smaller than the depth position D4.

Herein, in the transistor portion 70, by providing the back surface side lifetime control region 152, a recombination center may be formed to inhibit implantation of holes from the back surface 23 and thus lower a back surface avalanche withstand capability. Further, by forming the back surface side lifetime control region 152, the concentration of the one or more peaks of the buffer region 20 formed by hydrogen may become high. In the present example, the doping concentration between the third peak 123 and the fourth peak 124 has become high by the formation of the lifetime killer. When the doping concentration of the buffer region 20 becomes high, implantation of holes from the back surface 23 may be inhibited to thus lower the back surface avalanche withstand capability.

By providing the main region 156 implanted with the lifetime killer inside the diode portion 80 in the semiconductor device 100, a fall of the back surface avalanche withstand capability can be suppressed. Even when using an MCZ substrate with which the concentration of the buffer region 20 is apt to become high in the semiconductor device 100 of the present example, it is possible to avoid a situation where the concentration of the buffer region 20 becomes high and suppress a fall of the back surface avalanche withstand capability. Moreover, by not providing the lifetime control portion 150 in the transistor portion 70 in the semiconductor device 100, an increase in leak current and thermal runaway of elements can be suppressed.

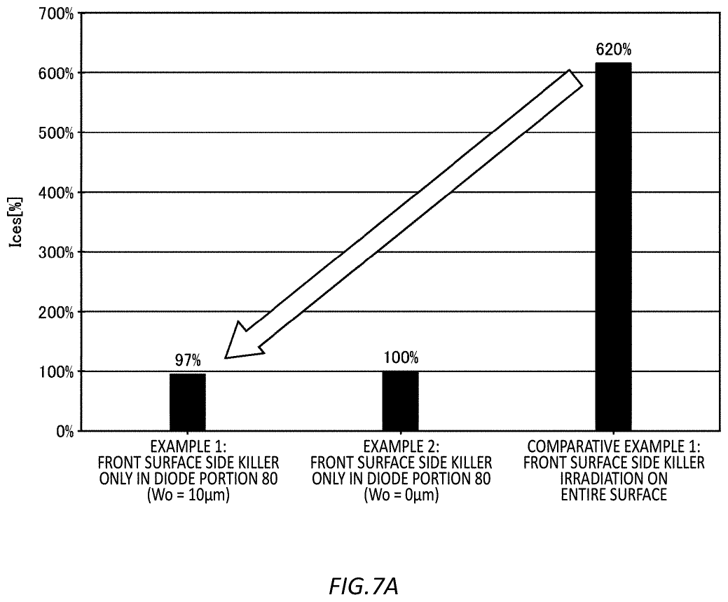

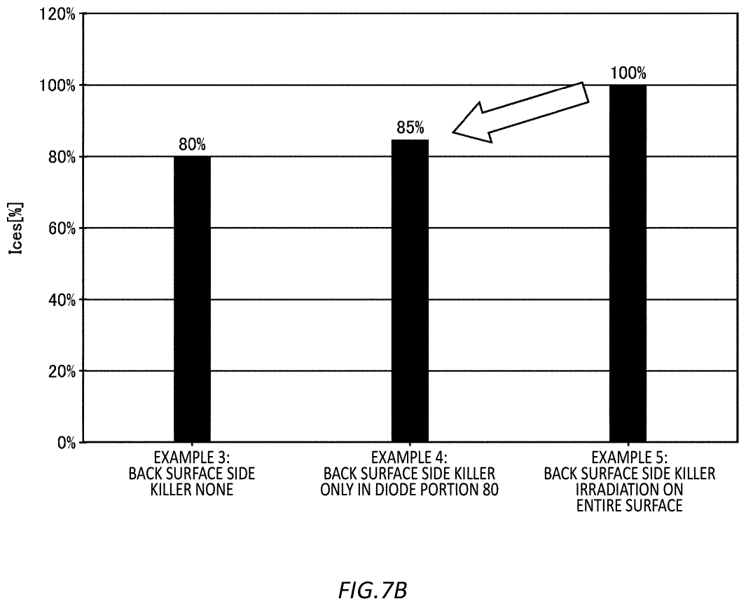

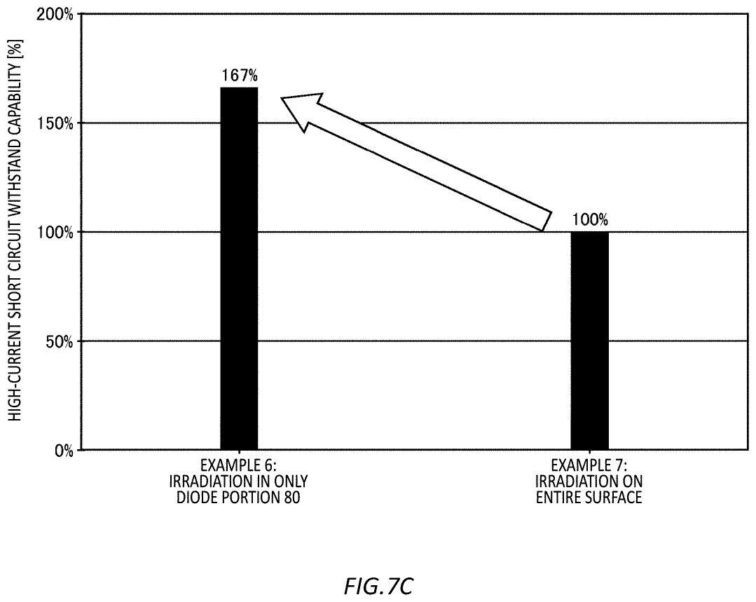

FIG. 7A shows a relationship between a collector-emitter shutdown current Ices and an implantation region of the front surface side lifetime control region 151. The collector-emitter shutdown current Ices is a collector-emitter leak current that is caused when a predetermined voltage is applied between the collector and the emitter in a state where gate-emitter is short-circuited.

Example 1 is an example of a case where the front surface side lifetime control region 151 is provided only in the diode portion 80, and the overlapping width Wo=10 μm. The overlapping width Wo indicates a width by which the mask for forming the lifetime control portion 150 overlaps with the diode portion 80. The overlapping width Wo will be described below.

Example 2 is an example of a case where the front surface side lifetime control region 151 is provided only in the diode portion 80, and the overlapping width Wo=0 μm. Comparative Example 1 is an example of a case where the front surface side lifetime control region 151 is implanted across the entire surface of the semiconductor substrate 10.

When the collector-emitter shutdown current Ices of Example 2 is 100%, Ices of Comparative Example 1 was 620%, and Ices of Example 1 was 97%. In this manner, by providing the front surface side lifetime control region 151 in only the diode portion 80, a leak current can be significantly reduced.

FIG. 7B shows a relationship between the collector-emitter shutdown current Ices and an implantation region of the back surface side lifetime control region 152.

Example 3 is an example of a case where the back surface side lifetime control region 152 is not provided. Example 4 is an example of a case where the back surface side lifetime control region 152 is provided in only the diode portion 80. Example 5 is an example of a case where the back surface side lifetime control region 152 is implanted across the entire surface of the semiconductor substrate 10.

When the collector-emitter shutdown current Ices of Example 5 is 100%, Ices of Example 3 was 80%, and Ices of Example 4 was 85%. In this manner, by changing the implantation region of the back surface side lifetime control region 152, a leak current amount can be adjusted. The region to provide the back surface side lifetime control region 152 may be determined as appropriate considering a trade-off with a switching loss and the like.

FIG. 7C shows a relationship between a high-current short circuit withstand capability and the implantation region of the back surface side lifetime control region 152. As an example, the high-current short circuit withstand capability is a maximum gate-emitter voltage value that can be shut off safely when the gate-emitter voltage is increased to +15 V or more and the semiconductor device 100 is caused to short-circuit.

Example 6 is an example of a case where the back surface side lifetime control region 152 is provided in only the diode portion 80. Example 7 is an example of a case where the back surface side lifetime control region 152 is implanted across the entire surface of the semiconductor substrate 10.

When the high-current short circuit withstand capability of Example 7 is 100%, the high-current short circuit withstand capability of Example 6 was 167%. In this manner, by changing the implantation region of the back surface side lifetime control region 152, the high-current short circuit withstand capability can be adjusted. The region to provide the back surface side lifetime control region 152 may be determined as appropriate considering a trade-off with a switching loss and the like.

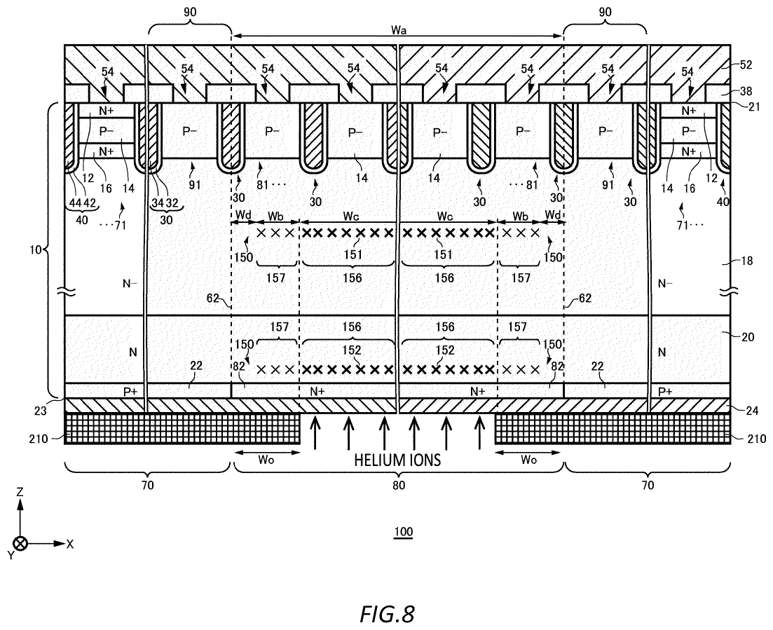

FIG. 8 shows an example of a helium ion implantation process that uses a mask 210. In the present example, the lifetime control portion 150 is selectively formed using the mask 210.

The mask 210 is formed on the front surface 21 or the back surface 23 of the semiconductor substrate 10 for forming the lifetime control portion 150. The mask 210 of the present example is provided on the back surface 23 side and suppresses implantation of helium ions into the semiconductor substrate 10. When helium ions are implanted from the front surface 21 side, the mask 210 is provided on the front surface 21 side. The lifetime control portion 150 is formed by implanting helium ions via a mask opening portion of the mask 210. That is, the mask opening portion of the mask 210 is provided in a region corresponding to the main region 156 where helium ions are to be implanted. On the other hand, the decay region 157 is covered by the mask 210.

In the present example, a lifetime killer is implanted via a uniform mask opening portion where the mask 210 is not formed. The mask 210 of the present example is not provided in the main region 156. Therefore, the main region 156 has a uniform doping concentration in a direction parallel to the front surface 21 of the semiconductor substrate 10. The uniform mask opening portion refers to a mask opening portion not having a repetitive structure in which an opened portion and an unopened portion of the mask are repetitively arranged as in a checkerboard pattern. On the other hand, when the repetitive structure such as a checkerboard pattern is provided in the main region 156 to form the lifetime control portion 150, the doping concentration of the lifetime control portion 150 may not become uniform.

The overlapping width Wo indicates a width by which the mask 210 overlaps with the diode portion 80. The overlapping width Wo may be equal to or larger than the diffusion half width at half maximum Wh by which the lifetime killer is diffused. The overlapping width Wo may be equal to a sum of the width Wb of the decay region 157 in the trench array direction and the distance Wd between the end portion of the decay region 157 and the boundary 62. In other words, of the overlapping width Wo of the mask 210 covering the diode portion 80, a width by which the lifetime killer is diffused is the width Wb, and the rest is the distance Wd.

Note that although the overlapping width Wo of the present example indicates the width by which the mask 210 overlaps with the diode portion 80 in the trench array direction, a width by which the mask 210 overlaps with the diode portion 80 in the trench extending direction may also be of a similar size.

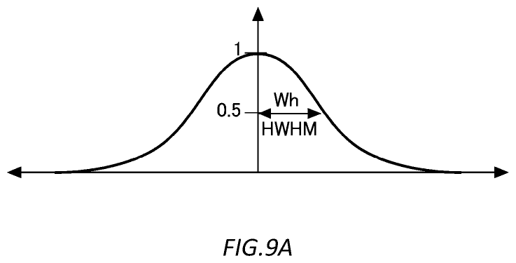

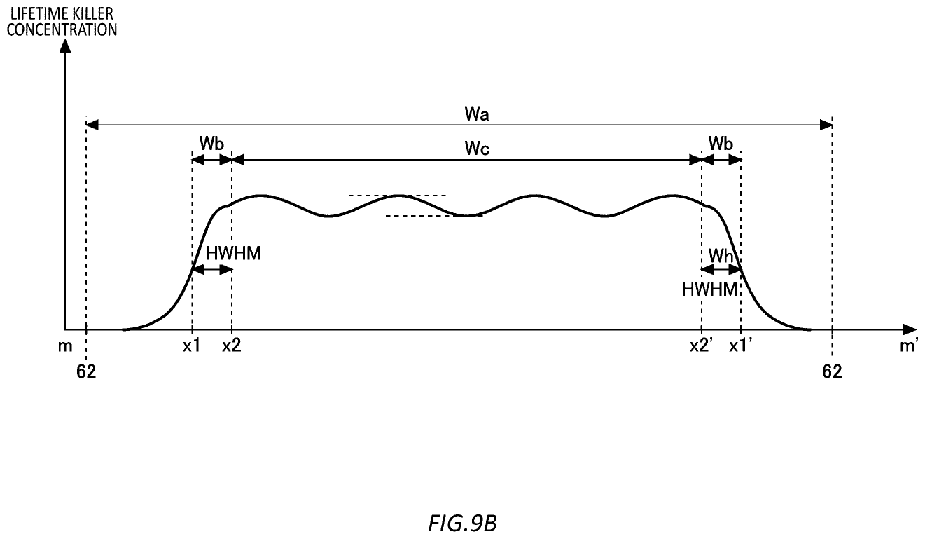

FIG. 9A is a diagram for describing the diffusion half width at half maximum Wh by which the lifetime killer is diffused. The diffusion half width at half maximum Wh may be a half width at half maximum (HWHM) of the lifetime killer concentration distribution after diffusion. The lifetime killer concentration of the main region 156 implanted with the lifetime killer becomes a lifetime killer concentration corresponding to a peak of the distribution. The decay region 157 not implanted with the lifetime killer has a lifetime killer concentration that has decayed along the lifetime killer concentration distribution shown in the present figure.

That is, the width Wb of the decay region 157 is the diffusion half width at half maximum Wh by which the lifetime killer for forming the main region 156 is diffused. The width Wb of the decay region 157 may be 0.1 μm or more and 10.0 μm or less. The width Wb of the decay region 157 may be the same in the trench array direction and the trench extending direction.

FIG. 9B is another example of the lifetime killer concentration distribution in the cross section m-m′ in FIG. 2A and the like. The lifetime killer concentration in the main region 156 may vary around the average concentration. Regarding a variation ratio of the lifetime killer concentration, a minimum value in the main region 156 may be 50% or more of a maximum value. Regarding the variation ratio of the lifetime killer concentration, a width between the maximum value and the minimum value may be 50% or less of the average concentration of the lifetime killer concentration in the main region 156. In such a case, the lifetime killer concentration distribution in the main region 156 may be assumed to be substantially flat or substantially uniform.

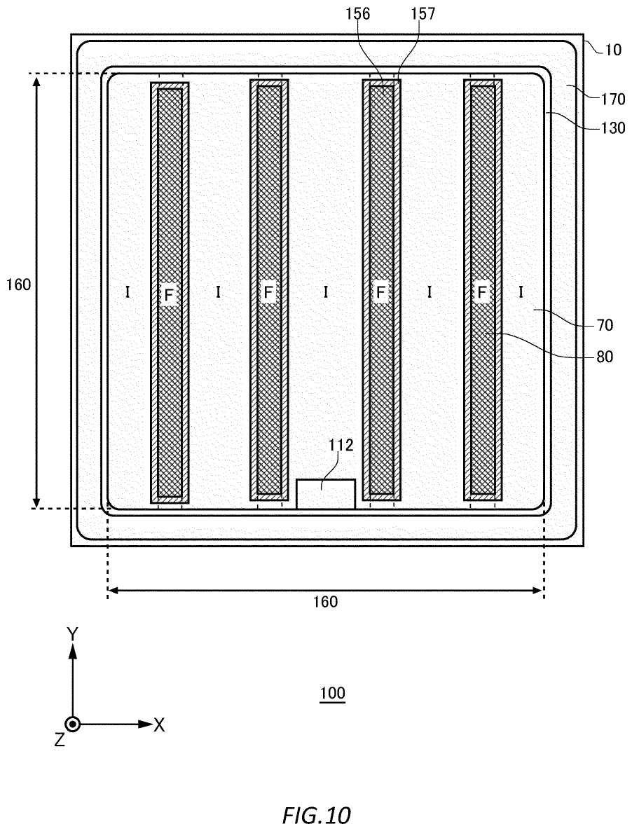

FIG. 10 shows an example of a top view of the semiconductor device 100. The present example shows regions where the main region 156 and the decay region 157 are provided in the top view of the semiconductor device 100 shown in FIG. 1A.

The main region 156 may be sandwiched between the decay regions 157 in the trench array direction. The main region 156 may be sandwiched between the decay regions 157 in the trench extending direction. The main region 156 of the present example is sandwiched between the decay regions 157 in each of the trench array direction and the trench extending direction. That is, the main region 156 of the present example is enclosed by the decay regions 157 in the direction parallel to the front surface 21 of the semiconductor substrate 10. The main region 156 and the decay region 157 may be the front surface side lifetime control region 151, or may be the back surface side lifetime control region 152.

The main region 156 may be provided in the same region as the diode portion 80. That is, the main region 156 may be provided in the same region as the cathode region 82 in the top view. The decay region 157 may be provided inside the transistor portion 70. That is, the decay region 157 may be provided to overlap with the collector region 22 in the top view. In this manner, in the present example, the mask opening portion of the mask 210 is provided in a region corresponding to the diode portion 80 in the top view, and the lifetime killer is then implanted, to thus form the main region 156 in the diode portion 80 and form the decay regions 157 around the diode portion 80.

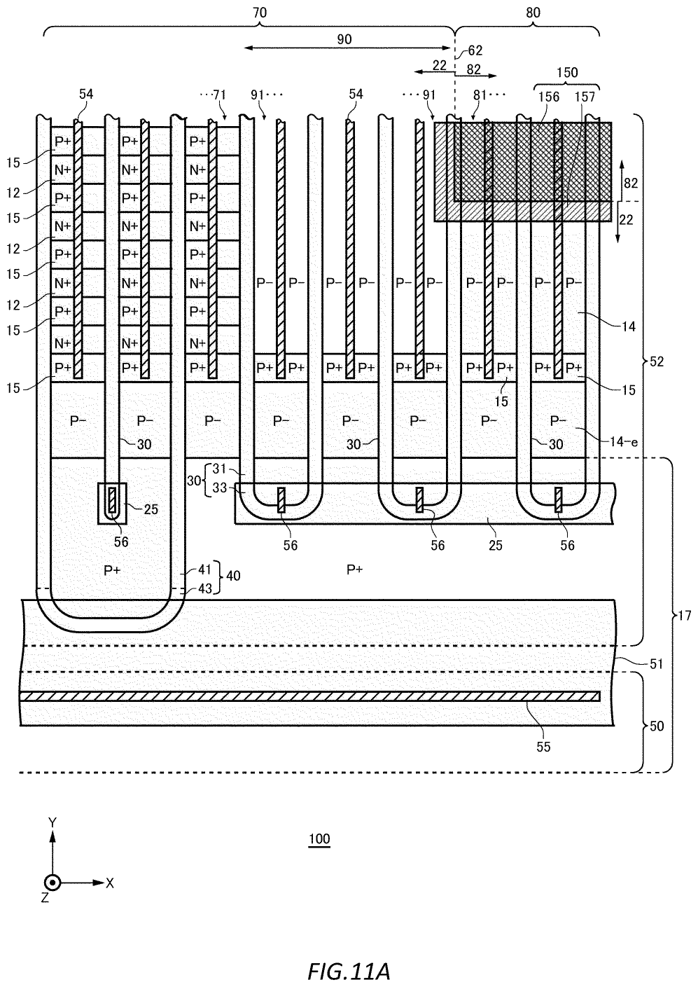

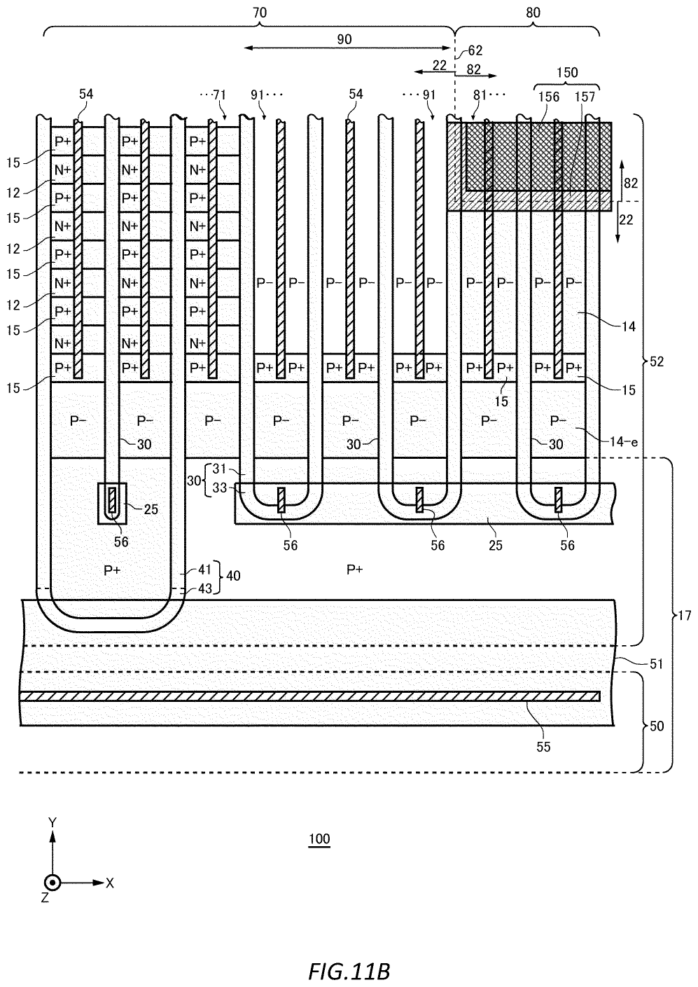

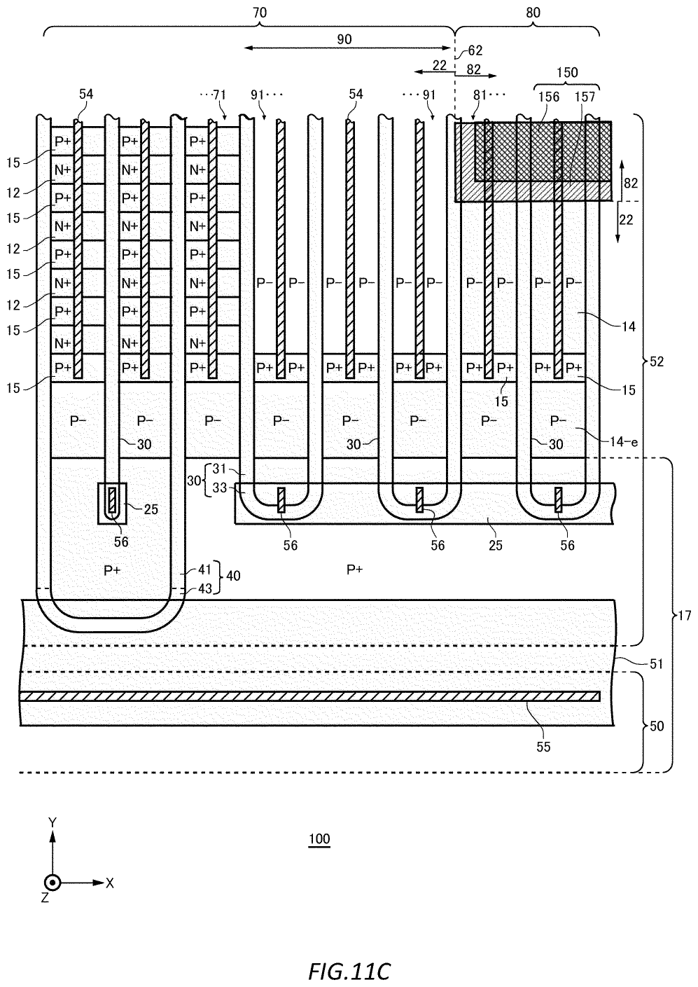

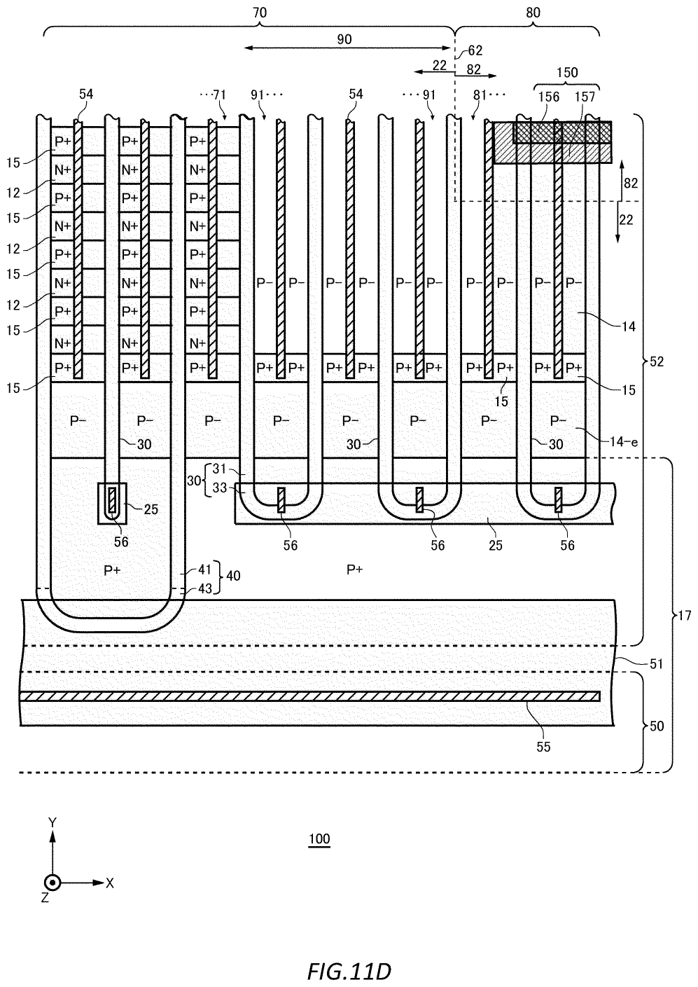

FIG. 11A is a top view showing a modified example of the semiconductor device 100. The present example differs from the top view of the semiconductor device 100 shown in FIG. 1B in that the positions of the main region 156 and the decay region 157 are illustrated. In the present example, differences with the semiconductor device 100 shown in FIG. 1B will be described in particular.

The main region 156 extends from the inside of the cathode region 82 to the boundary 62 between the collector region 22 and the cathode region 82 in the top view. The main region 156 of the present example extends from the inside of the cathode region 82 to the boundary 62 between the collector region 22 and the cathode region 82 in both the trench array direction and the trench extending direction.

The decay region 157 extends from the boundary 62 between the collector region 22 and the cathode region 82 to the inside of the collector region 22 in the top view. The decay region 157 of the present example extends from the boundary 62 between the collector region 22 and the cathode region 82 to the inside of the collector region 22 in both the trench array direction and the trench extending direction. The width of the decay region 157 may be the same in the trench array direction and the trench extending direction. The width of the decay region 157 in the trench array direction and the width thereof in the trench extending direction may both be the diffusion half width at half maximum Wh.

FIG. 11B is a top view showing a modified example of the semiconductor device 100. In the present example, the positions of the main region 156 and the decay region 157 differ from those in the top view of the semiconductor device 100 shown in FIG. 11A. In the present example, differences with the semiconductor device 100 shown in FIG. 11A will be described in particular.

The main region 156 extends from the inside of the cathode region 82 in the direction parallel to the front surface 21 of the semiconductor substrate 10 in the top view, and is terminated without extending to the boundary 62 between the collector region 22 and the cathode region 82. In both the trench array direction and the trench extending direction, the main region 156 of the present example extends from the inside of the cathode region 82 in the direction parallel to the front surface 21 of the semiconductor substrate 10, and is terminated without extending to the boundary 62 between the collector region 22 and the cathode region 82.

The decay region 157 extends from the main region 156 to the inside of the collector region 22 beyond the boundary 62 between the collector region 22 and the cathode region 82 in the top view. In both the trench array direction and the trench extending direction, the decay region 157 of the present example extends from the main region 156 to the inside of the collector region 22 beyond the boundary 62 between the collector region 22 and the cathode region 82.

FIG. 11C is a top view showing a modified example of the semiconductor device 100. In the present example, the positions of the main region 156 and the decay region 157 differ from those in the top view of the semiconductor device 100 shown in FIGS. 11A and 11B. In the present example, differences with the semiconductor device 100 shown in FIGS. 11A and 11B will be described in particular.

The main region 156 extends from the inside of the cathode region 82 in the direction parallel to the front surface 21 of the semiconductor substrate 10 in the top view, and is terminated without extending to the boundary 62 between the collector region 22 and the cathode region 82. In both the trench array direction and the trench extending direction, the main region 156 of the present example extends from the inside of the cathode region 82 in the direction parallel to the front surface 21 of the semiconductor substrate 10, and is terminated without extending to the boundary 62 between the collector region 22 and the cathode region 82.

The decay region 157 extends from the main region 156 to the boundary 62 between the collector region 22 and the cathode region 82 in the direction parallel to the front surface 21 of the semiconductor substrate 10 in the top view, and is terminated at the boundary 62. In both the trench array direction and the trench extending direction, the decay region 157 of the present example extends from the main region 156 to the boundary 62 between the collector region 22 and the cathode region 82, and is terminated at the boundary 62.

FIG. 11D is a top view showing a modified example of the semiconductor device 100. In the present example, the positions of the main region 156 and the decay region 157 differ from those in the top view of the semiconductor device 100 shown in FIGS. 11A to 11C. In the present example, differences with the semiconductor device 100 shown in FIGS. 11A to 11C will be described in particular.

The main region 156 extends from the inside of the cathode region 82 in the direction parallel to the front surface 21 of the semiconductor substrate 10 in the top view, and is terminated without extending to the boundary 62 between the collector region 22 and the cathode region 82. In both the trench array direction and the trench extending direction, the main region 156 of the present example extends from the inside of the cathode region 82 in the direction parallel to the front surface 21 of the semiconductor substrate 10, and is terminated without extending to the boundary 62 between the collector region 22 and the cathode region 82.

The decay region 157 extends from the main region 156 in the direction parallel to the front surface 21 of the semiconductor substrate 10 in the top view, and is terminated without extending to the boundary 62 between the collector region 22 and the cathode region 82. In both the trench array direction and the trench extending direction, the decay region 157 of the present example extends from the main region 156 in the direction parallel to the front surface 21 of the semiconductor substrate 10, and is terminated without extending to the boundary 62 between the collector region 22 and the cathode region 82.

The distance between the boundary 62 and the decay region 157 may be the same in the trench array direction and the trench extending direction, or may differ between the trench array direction and the trench extending direction. The distance between the boundary 62 and the decay region 157 may be the same as the diffusion half width at half maximum Wh, may be larger than the diffusion half width at half maximum Wh, or may be smaller than the diffusion half width at half maximum Wh.

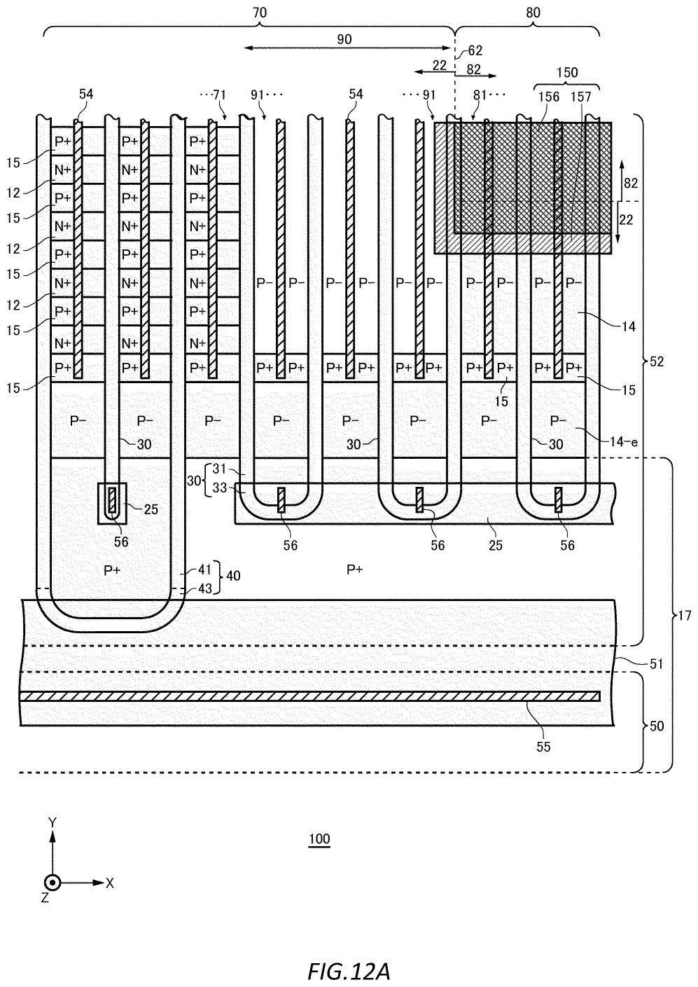

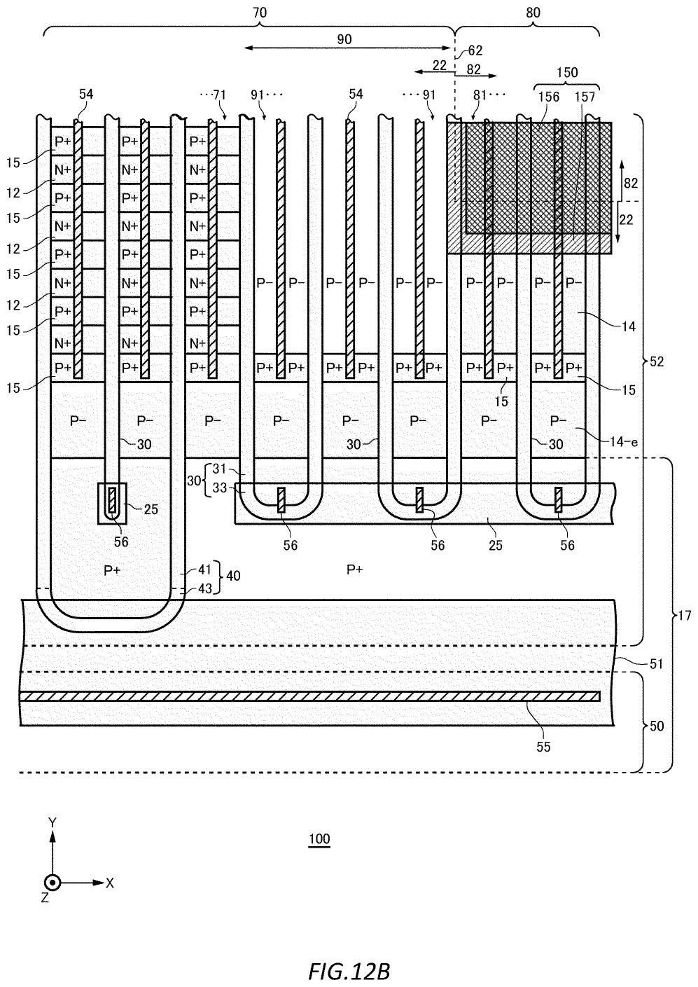

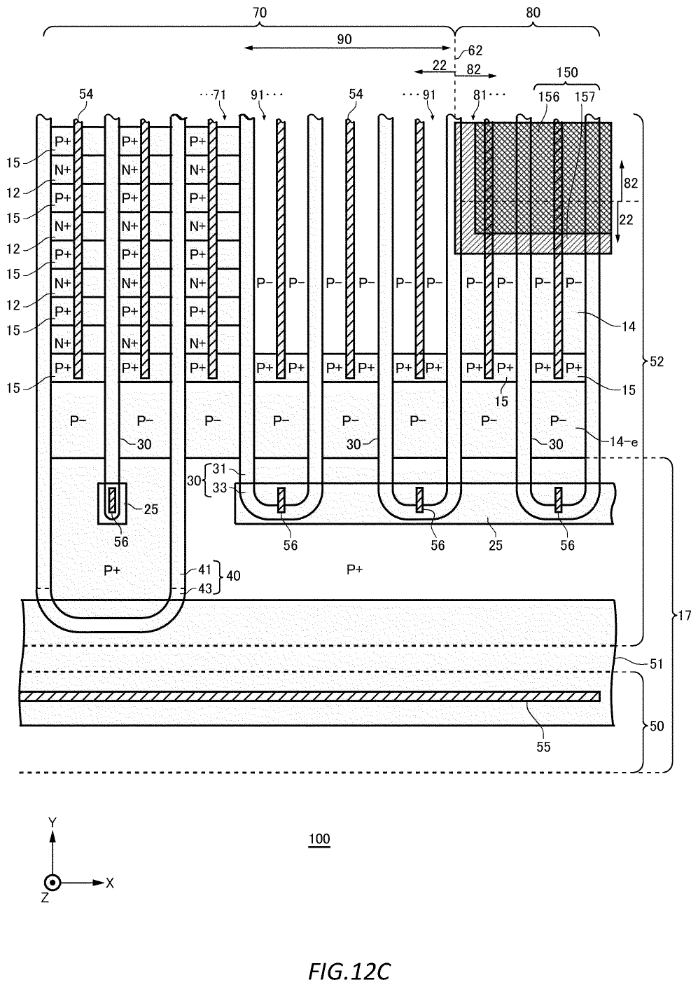

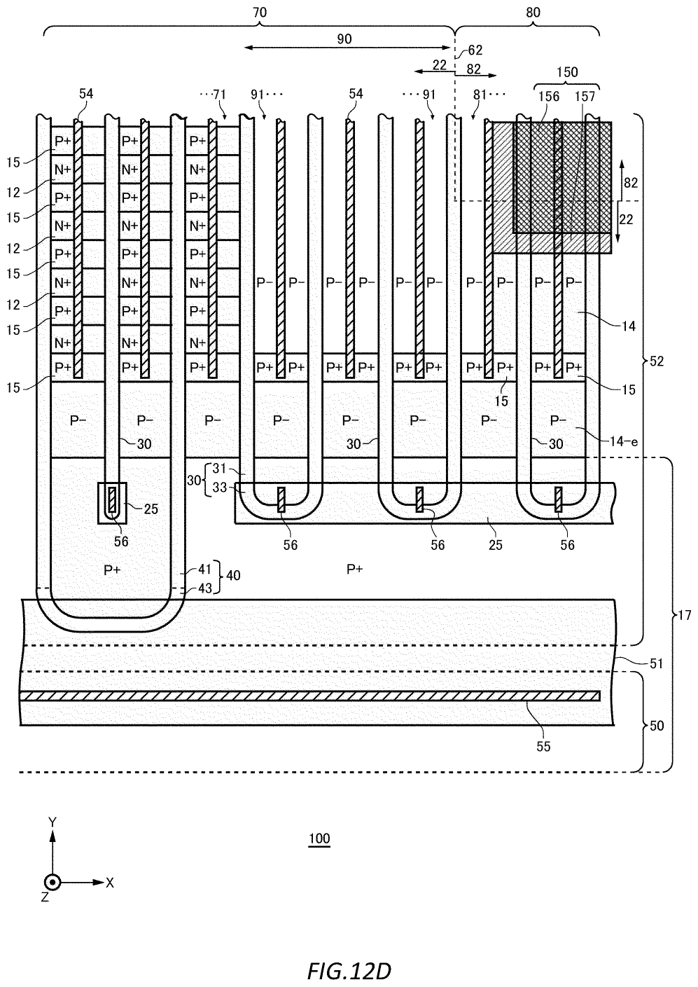

FIG. 12A is a top view showing a modified example of the semiconductor device 100. In the present example, the positions of the main region 156 and the decay region 157 in the trench extending direction differ from those in the top view of the semiconductor device 100 shown in FIG. 11A. In the present example, differences with the semiconductor device 100 shown in FIG. 11A will be described in particular.

The main region 156 extends from the inside of the cathode region 82 to the inside of the collector region 22 beyond the boundary 62 between the collector region 22 and the cathode region 82 in the trench extending direction. On the other hand, the main region 156 extends from the inside of the cathode region 82 to the boundary 62 between the collector region 22 and the cathode region 82 in the trench array direction. In this manner, the main region 156 may be provided to extend to different positions in the trench array direction and the trench extending direction regarding the relationship with the boundary 62.

The decay region 157 extends from the main region 156 in the direction parallel to the front surface 21 of the semiconductor substrate 10 in the trench extending direction, and is terminated inside the collector region 22. On the other hand, the decay region 157 extends from the boundary 62 between the collector region 22 and the cathode region 82 to the inside of the collector region 22 in the trench array direction. The width of the decay region 157 may be the same in the trench array direction and the trench extending direction. The decay region 157 may be provided to extend to different positions in the trench array direction and the trench extending direction regarding the relationship with the boundary 62.

In the semiconductor device 100 of the present example, by providing the lifetime control portion 150 such that it extends beyond the boundary 62 at the end portion of the diode portion 80 in the trench extending direction, it becomes easy to avoid a destructive failure of elements during reverse recovery.

FIG. 12B is a top view showing a modified example of the semiconductor device 100. In the present example, the positions of the main region 156 and the decay region 157 in the trench extending direction differ from those in the top view of the semiconductor device 100 shown in FIG. 11B. In the present example, differences with the semiconductor device 100 shown in FIG. 11B will be described in particular.

The main region 156 extends from the inside of the cathode region 82 to the inside of the collector region 22 beyond the boundary 62 between the collector region 22 and the cathode region 82 in the trench extending direction. On the other hand, the main region 156 extends from the inside of the cathode region 82 in the direction parallel to the front surface 21 of the semiconductor substrate 10 in the trench array direction, and is terminated without extending to the boundary 62 between the collector region 22 and the cathode region 82. In this manner, the main region 156 may be provided to extend to different positions in the trench array direction and the trench extending direction regarding the relationship with the boundary 62.

The decay region 157 extends from the main region 156 in the direction parallel to the front surface 21 of the semiconductor substrate 10 in the trench extending direction, and is terminated inside the collector region 22. On the other hand, the decay region 157 extends from the main region 156 to the inside of the collector region 22 beyond the boundary 62 between the collector region 22 and the cathode region 82 in the trench array direction. The width of the decay region 157 may be the same in the trench array direction and the trench extending direction. The decay region 157 may be provided to extend to different positions in the trench array direction and the trench extending direction regarding the relationship with the boundary 62.

FIG. 12C is a top view showing a modified example of the semiconductor device 100. In the present example, the positions of the main region 156 and the decay region 157 in the trench extending direction differ from those in the top view of the semiconductor device 100 shown in FIG. 11C. In the present example, differences with the semiconductor device 100 shown in FIG. 11C will be described in particular.

The main region 156 extends from the inside of the cathode region 82 to the inside of the collector region 22 beyond the boundary 62 between the collector region 22 and the cathode region 82 in the trench extending direction. On the other hand, the main region 156 extends from the inside of the cathode region 82 in the direction parallel to the front surface 21 of the semiconductor substrate 10 in the trench array direction, and is terminated without extending to the boundary 62 between the collector region 22 and the cathode region 82. In this manner, the main region 156 may be provided to extend to different positions in the trench array direction and the trench extending direction regarding the relationship with the boundary 62.

The decay region 157 extends from the main region 156 in the direction parallel to the front surface 21 of the semiconductor substrate 10 in the trench extending direction, and is terminated inside the collector region 22. On the other hand, the decay region 157 extends from the main region 156 to the boundary 62 between the collector region 22 and the cathode region 82 in the trench array direction, and is terminated at the boundary 62. The width of the decay region 157 may be the same in the trench array direction and the trench extending direction. The decay region 157 may be provided to extend to different positions in the trench array direction and the trench extending direction regarding the relationship with the boundary 62.

FIG. 12D is a top view showing a modified example of the semiconductor device 100. In the present example, the positions of the main region 156 and the decay region 157 in the trench extending direction differ from those in the top view of the semiconductor device 100 shown in FIG. 11D. In the present example, differences with the semiconductor device 100 shown in FIG. 11D will be described in particular.

The main region 156 extends from the inside of the cathode region 82 to the inside of the collector region 22 beyond the boundary 62 between the collector region 22 and the cathode region 82 in the trench extending direction. On the other hand, the main region 156 extends from the inside of the cathode region 82 in the direction parallel to the front surface 21 of the semiconductor substrate 10 in the trench array direction, and is terminated without extending to the boundary 62 between the collector region 22 and the cathode region 82. In this manner, the main region 156 may be provided to extend to different positions in the trench array direction and the trench extending direction regarding the relationship with the boundary 62.

The decay region 157 extends from the main region 156 in the direction parallel to the front surface 21 of the semiconductor substrate 10 in the trench extending direction, and is terminated inside the collector region 22. On the other hand, the decay region 157 extends from the main region 156 in the direction parallel to the front surface 21 of the semiconductor substrate 10 in the trench array direction, and is terminated without extending to the boundary 62 between the collector region 22 and the cathode region 82. The width of the decay region 157 may be the same in the trench array direction and the trench extending direction. The decay region 157 may be provided to extend to different positions in the trench array direction and the trench extending direction regarding the relationship with the boundary 62.

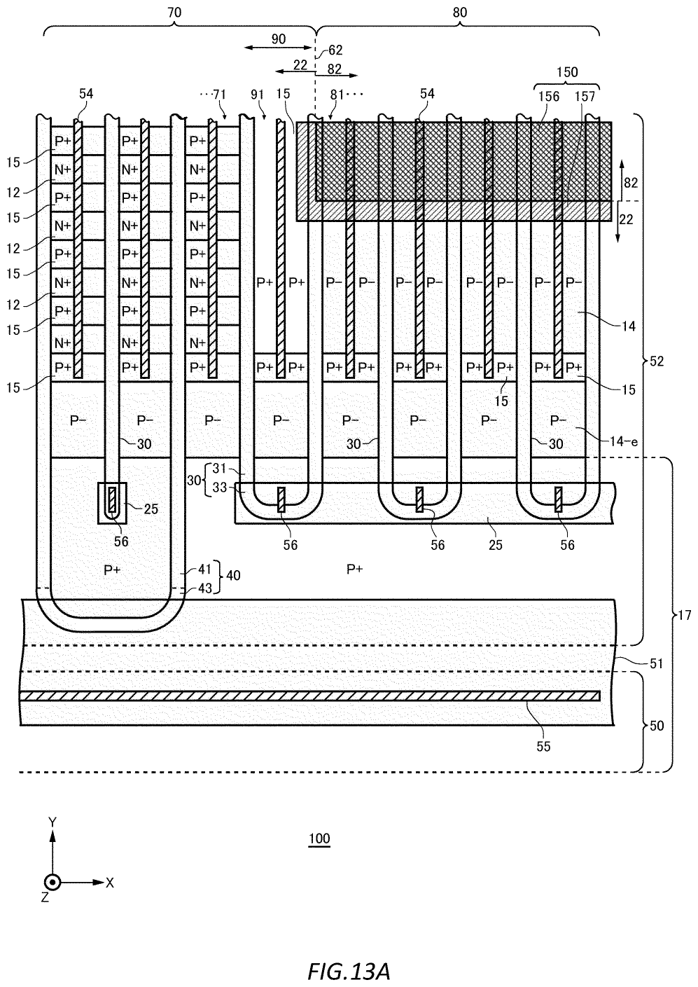

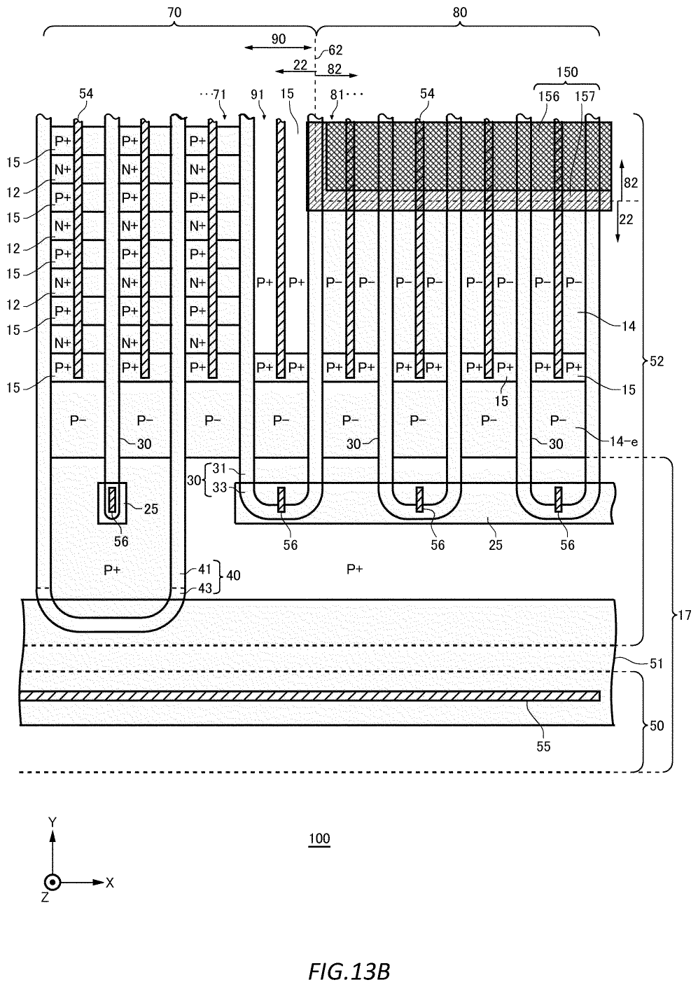

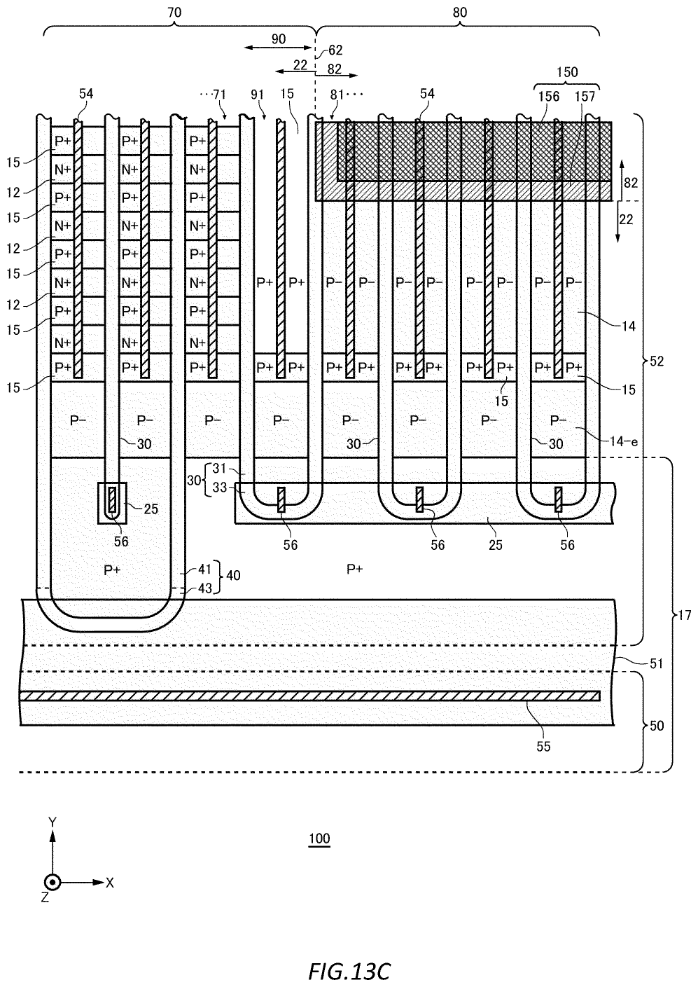

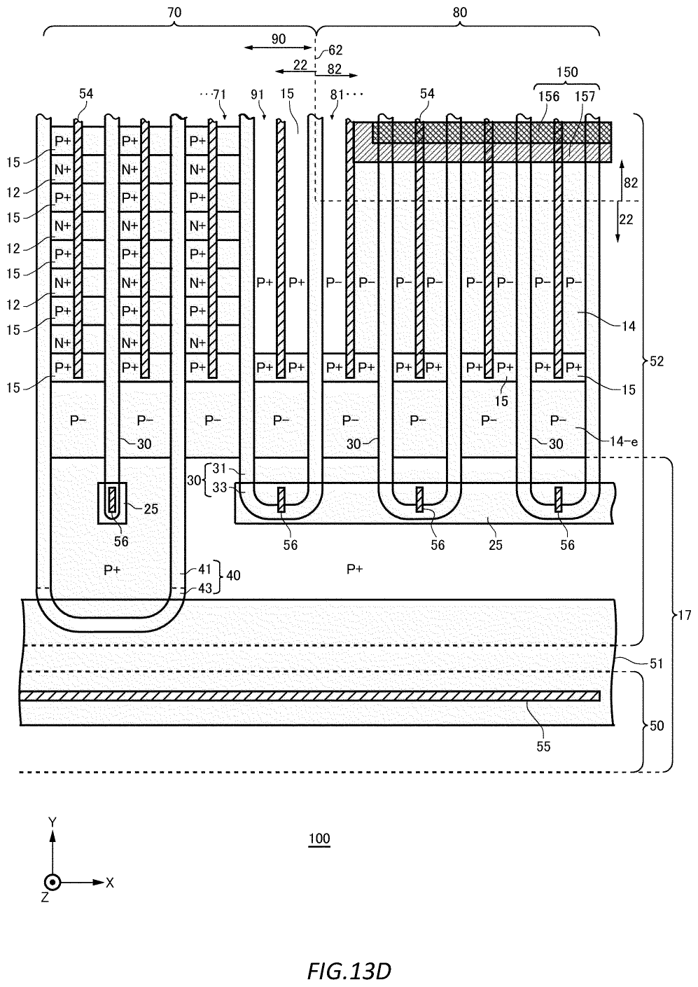

FIG. 13A is a top view showing a modified example of the semiconductor device 100. The present example differs from the top view of the semiconductor device 100 shown in FIG. 11A in that the boundary region 90 includes the contact region 15. In the present example, differences with the semiconductor device 100 shown in FIG. 11A will be described in particular.

The boundary region 90 includes the contact region 15 on the front surface 21 of the mesa portion 91. The mesa portion 91 of the present example includes only the contact region 15 in a region sandwiched between the base regions 14-e in the top view. Note that the mesa portion 91 may include both the base region 14 and the contact region 15 in the region sandwiched between the base regions 14-e in the top view.

The main region 156 extends from the inside of the cathode region 82 to the boundary 62 between the collector region 22 and the cathode region 82 in both the trench array direction and the trench extending direction. The decay region 157 extends from the boundary 62 between the collector region 22 and the cathode region 82 to the inside of the collector region 22 in both the trench array direction and the trench extending direction. The decay region 157 of the present example extends to the mesa portion 91 in the trench array direction in the top view, and is also provided in a region overlapping with the contact region 15.

FIG. 13B is a top view showing a modified example of the semiconductor device 100. The present example differs from the top view of the semiconductor device 100 shown in FIG. 11B in that the boundary region 90 includes the contact region 15. In the present example, differences with the semiconductor device 100 shown in FIG. 11B will be described in particular.

In both the trench array direction and the trench extending direction, the main region 156 extends from the inside of the cathode region 82 in the direction parallel to the front surface 21 of the semiconductor substrate 10, and is terminated without extending to the boundary 62 between the collector region 22 and the cathode region 82. In both the trench array direction and the trench extending direction, the decay region 157 extends from the main region 156 to the inside of the collector region 22 beyond the boundary 62 between the collector region 22 and the cathode region 82.

FIG. 13C is a top view showing a modified example of the semiconductor device 100. The present example differs from the top view of the semiconductor device 100 shown in FIG. 11C in that the boundary region 90 includes the contact region 15. In the present example, differences with the semiconductor device 100 shown in FIG. 11C will be described in particular.

In both the trench array direction and the trench extending direction, the main region 156 extends from the inside of the cathode region 82 in the direction parallel to the front surface 21 of the semiconductor substrate 10, and is terminated without extending to the boundary 62 between the collector region 22 and the cathode region 82. In both the trench array direction and the trench extending direction, the decay region 157 extends from the main region 156 to the boundary 62 between the collector region 22 and the cathode region 82, and is terminated at the boundary 62.

FIG. 13D is a top view showing a modified example of the semiconductor device 100. The present example differs from the top view of the semiconductor device 100 shown in FIG. 11D in that the boundary region 90 includes the contact region 15. In the present example, differences with the semiconductor device 100 shown in FIG. 11D will be described in particular.

In both the trench array direction and the trench extending direction, the main region 156 extends from the inside of the cathode region 82 in the direction parallel to the front surface 21 of the semiconductor substrate 10, and is terminated without extending to the boundary 62 between the collector region 22 and the cathode region 82. In both the trench array direction and the trench extending direction, the decay region 157 extends from the main region 156 in the direction parallel to the front surface 21 of the semiconductor substrate 10, and is terminated without extending to the boundary 62 between the collector region 22 and the cathode region 82.

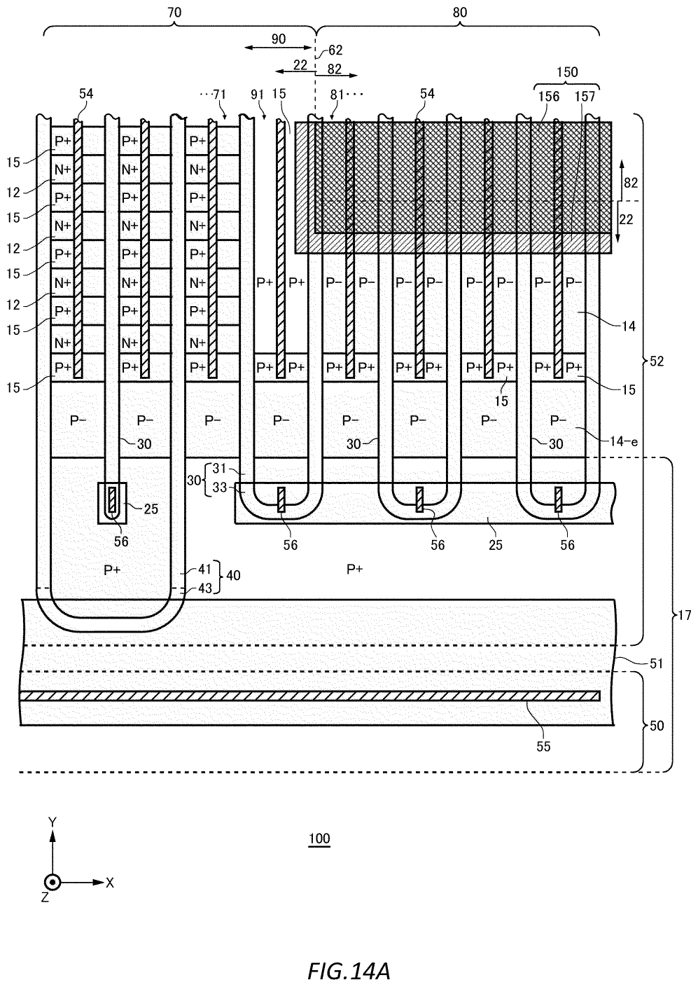

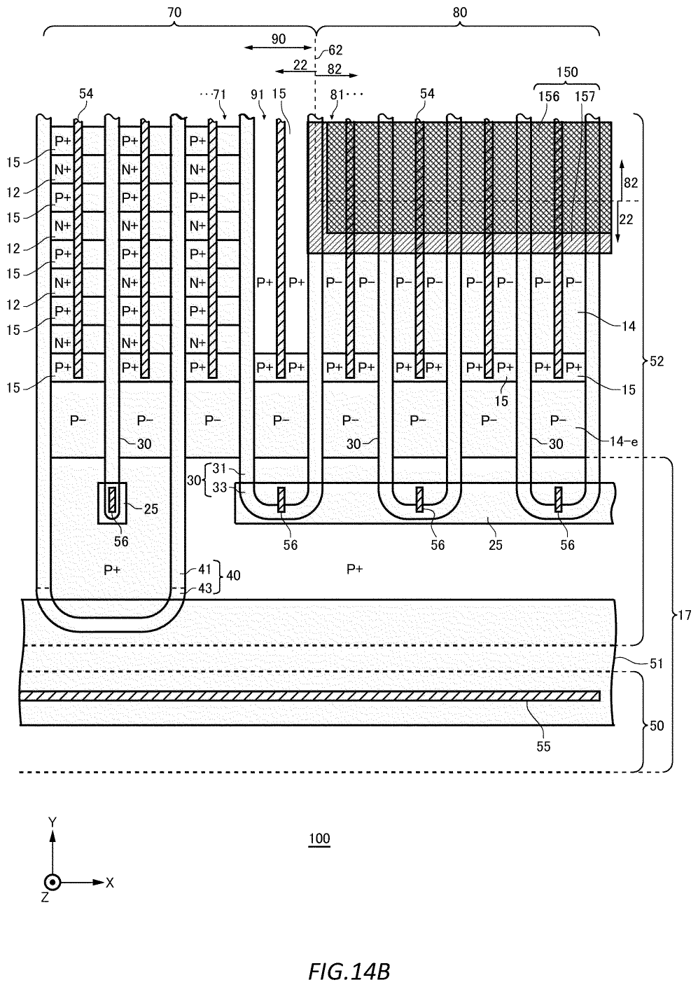

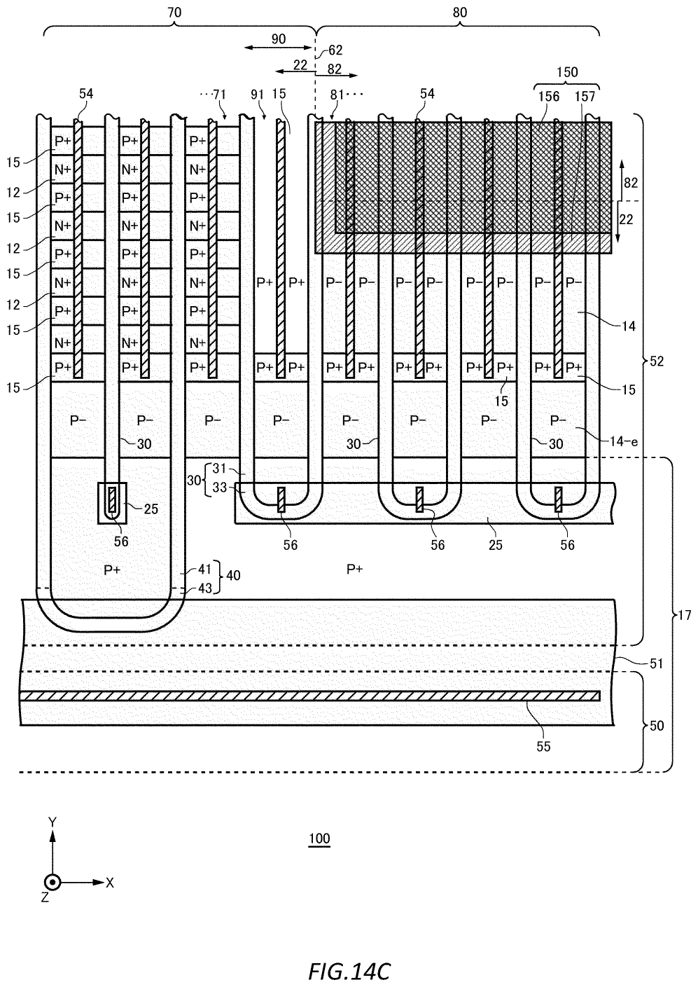

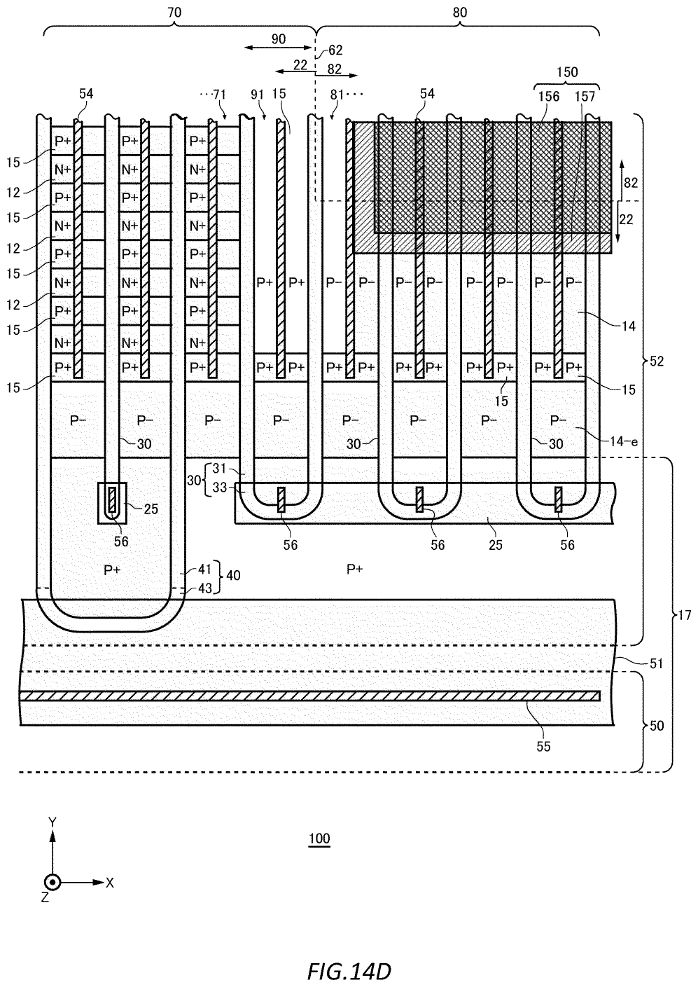

FIG. 14A is a top view showing a modified example of the semiconductor device 100. The present example differs from the top view of the semiconductor device 100 shown in FIG. 12A in that the boundary region 90 includes the contact region 15. In the present example, differences with the semiconductor device 100 shown in FIG. 12A will be described in particular. Similar to FIG. 13A, the semiconductor device 100 of the present example includes the contact region 15 in the mesa portion 91 of the boundary region 90.

The main region 156 extends from the inside of the cathode region 82 to the boundary 62 between the collector region 22 and the cathode region 82 in the trench array direction. The decay region 157 extends from the boundary 62 between the collector region 22 and the cathode region 82 to the inside of the collector region 22 in the trench array direction. The decay region 157 of the present example extends to the mesa portion 91 in the trench array direction in the top view, and is also provided in a region overlapping with the contact region 15.

FIG. 14B is a top view showing a modified example of the semiconductor device 100. The present example differs from the top view of the semiconductor device 100 shown in FIG. 12B in that the boundary region 90 includes the contact region 15.

The main region 156 is terminated without extending to the boundary 62 between the collector region 22 and the cathode region 82 in the trench array direction, but extends to the inside of the collector region 22 beyond the boundary 62 between the collector region 22 and the cathode region 82 in the trench extending direction.

The decay region 157 extends to the inside of the collector region 22 beyond the boundary 62 between the collector region 22 and the cathode region 82 in the trench array direction, and extends from the main region 156 in the direction parallel to the front surface 21 of the semiconductor substrate 10 to be terminated inside the collector region 22 in the trench extending direction.

FIG. 14C is a top view showing a modified example of the semiconductor device 100. The present example differs from the top view of the semiconductor device 100 shown in FIG. 12C in that the boundary region 90 includes the contact region 15.

The main region 156 is terminated without extending to the boundary 62 between the collector region 22 and the cathode region 82 in the trench array direction, but extends to the inside of the collector region 22 beyond the boundary 62 between the collector region 22 and the cathode region 82 in the trench extending direction.

The decay region 157 extends from the main region 156 to the boundary 62 between the collector region 22 and the cathode region 82 to be terminated at the boundary 62 in the trench array direction, but extends from the main region 156 in the direction parallel to the front surface 21 of the semiconductor substrate 10 to be terminated inside the collector region 22 in the trench extending direction.

FIG. 14D is a top view showing a modified example of the semiconductor device 100. The present example differs from the top view of the semiconductor device 100 shown in FIG. 12D in that the boundary region 90 includes the contact region 15.

The main region 156 is terminated without extending to the boundary 62 between the collector region 22 and the cathode region 82 in the trench array direction, but extends to the inside of the collector region 22 beyond the boundary 62 between the collector region 22 and the cathode region 82 in the trench extending direction.

The decay region 157 is terminated without extending to the boundary 62 between the collector region 22 and the cathode region 82 in the trench array direction, and extends from the main region 156 in the direction parallel to the front surface 21 of the semiconductor substrate 10 to be terminated inside the collector region 22 in the trench extending direction.

In this manner, in the semiconductor device 100, the main region 156 and the decay region 157 can be arranged in various forms as disclosed in the examples shown in FIGS. 11A to 14D. The lifetime control portion 150 disclosed in the examples shown in FIGS. 11A to 14D may be the front surface side lifetime control region 151, may be the back surface side lifetime control region 152, or may be both of the front surface side lifetime control region 151 and the back surface side lifetime control region 152. When the lifetime control portion 150 is the front surface side lifetime control region 151, the back surface side lifetime control region 152 may be provided across the entire surface of the semiconductor substrate 10, or may be omitted.

While the present invention has been described with the embodiments, the technical scope of the present invention is not limited to the above-described embodiments. It is apparent to persons skilled in the art that various alterations and improvements can be added to the above-described embodiments. It is also apparent from the description of the claims that the embodiments to which such alterations or improvements are made can be included in the technical scope of the present invention.

The operations, procedures, steps, and stages of each process performed by an apparatus, system, program, and method shown in the claims, specification, or drawings can be performed in any order as long as the order is not indicated by “prior to,” “before,” or the like and as long as the output from a previous process is not used in a later process. Even if the process flow is described using phrases such as “first” or “next” in the claims, specification, or drawings, it does not necessarily mean that the process must be performed in this order.

### EXPLANATION OF REFERENCES

10: semiconductor substrate; 12: emitter region; 14: base region; 15: contact region; 16: accumulation region; 17: well region; 18: drift region; 20: buffer region; 21: front surface; 22: collector region; 23: back surface; 24: collector electrode; 25: connection portion; 30: dummy trench portion; 31: extending portion; 32: dummy dielectric film; 33: connecting portion; 34: dummy conductive portion; 38: interlayer dielectric film; 40: gate trench portion; 41: extending portion; 42: gate dielectric film; 43: connecting portion; 44: gate conductive portion; 50: gate metal layer; 51: gate runner portion; 52: emitter electrode; 54: contact hole; 55: contact hole; 56: contact hole; 62: boundary; 70: transistor portion; 71: mesa portion; 80: diode portion; 81: mesa portion; 82: cathode region; 90: boundary region; 91: mesa portion; 100: semiconductor device; 102: end side; 112: gate pad; 121: first peak; 122: second peak; 123: third peak; 124: fourth peak; 130: gate runner; 150: lifetime control portion; 151: front surface side lifetime control region; 152: back surface side lifetime control region; 156: main region; 157: decay region; 158: seeping portion; 160: active portion; 170: edge termination structure portion; 210: mask.

What is claimed is:

1. A semiconductor device including a transistor portion and a diode portion, comprising:
a drift region of a first conductivity type, which is provided in a semiconductor substrate;
a collector region of a second conductivity type, which is provided on a back surface of the semiconductor substrate;
a cathode region of the first conductivity type, which is provided on the back surface of the semiconductor substrate and has a higher doping concentration than the drift region;
a plurality of trench portions provided on a front surface of the semiconductor substrate; and
a lifetime control portion which is provided in the semiconductor substrate and contains a lifetime killer,
wherein the lifetime control portion includes:
a main region provided in the diode portion; and
a decay region which is provided to extend from the main region in a direction parallel to the front surface of the semiconductor substrate and has a lifetime killer concentration that has decayed more than a lifetime killer concentration of the main region.

2. The semiconductor device according to claim 1, wherein
the decay region is provided to extend from the main region in the direction parallel to the front surface of the semiconductor substrate in the diode portion.

3. The semiconductor device according to claim 1, wherein
the decay region extends from the main region to a boundary between the collector region and the cathode region in a top view.

4. The semiconductor device according to claim 1, wherein
the decay region extends from the main region to an inside of the collector region beyond a boundary between the collector region and the cathode region in a top view.

5. The semiconductor device according to claim 1, wherein
the main region extends from an inside of the cathode region to a boundary between the collector region and the cathode region in a top view, and
the decay region extends from the boundary between the collector region and the cathode region to an inside of the collector region in the top view.

6. The semiconductor device according to claim 1, wherein
the main region extends from an inside of the cathode region in the direction parallel to the front surface of the semiconductor substrate, and is terminated without extending to a boundary between the collector region and the cathode region in a top view, and
the decay region extends from the main region to an inside of the collector region beyond the boundary between the collector region and the cathode region in the top view.

7. The semiconductor device according to claim 1, wherein
the main region extends from an inside of the cathode region in the direction parallel to the front surface of the semiconductor substrate, and is terminated without extending to a boundary between the collector region and the cathode region in a top view, and
the decay region extends from the main region to the boundary between the collector region and the cathode region in the direction parallel to the front surface of the semiconductor substrate, and is terminated at the boundary in the top view.

8. A semiconductor device including a transistor portion and a diode portion, comprising:
a drift region of a first conductivity type, which is provided in a semiconductor substrate;
a collector region of a second conductivity type, which is provided on a back surface of the semiconductor substrate;
a cathode region of the first conductivity type, which is provided on the back surface of the semiconductor substrate and has a higher doping concentration than the drift region;
a plurality of trench portions provided on a front surface of the semiconductor substrate; and
a lifetime control portion which is provided in the semiconductor substrate and contains a lifetime killer,
wherein the lifetime control portion extends from an inside of the cathode region in a direction parallel to the front surface of the semiconductor substrate, and is terminated without extending to a boundary between the collector region and the cathode region in a top view.

9. The semiconductor device according to claim 8, wherein
the lifetime control portion includes:
a main region provided in the diode portion; and
a decay region which is provided to extend from the main region in the direction parallel to the front surface of the semiconductor substrate and has a lifetime killer concentration that has decayed more than a lifetime killer concentration of the main region,
the main region extends from the inside of the cathode region in the direction parallel to the front surface of the semiconductor substrate, and is terminated without extending to the boundary between the collector region and the cathode region in the top view, and
the decay region extends from the main region in the direction parallel to the front surface of the semiconductor substrate, and is terminated without extending to the boundary between the collector region and the cathode region in the top view.

10. The semiconductor device according to claim 1, wherein
the lifetime control portion is a front surface side lifetime control region provided closer to the front surface than a center of the semiconductor substrate in a depth direction.

11. The semiconductor device according to claim 10, wherein
the lifetime control portion includes a back surface side lifetime control region which is provided closer to the back surface than the center of the semiconductor substrate in the depth direction and is provided across an entire surface of the semiconductor substrate.

12. The semiconductor device according to claim 1, wherein
the lifetime control portion is a back surface side lifetime control region provided closer to the back surface of the semiconductor substrate than a center of the semiconductor substrate in a depth direction.

13. The semiconductor device according to claim 12, comprising:
a buffer region of the first conductivity type, which is provided closer to the back surface of the semiconductor substrate than the center of the semiconductor substrate in the depth direction,
wherein the buffer region has one or more peaks of a doping concentration in the depth direction of the semiconductor substrate.

14. The semiconductor device according to claim 13, wherein
the one or more peaks contain a hydrogen donor.

15. The semiconductor device according to claim 13, wherein
the buffer region has four peaks of the doping concentration in the depth direction of the semiconductor substrate, and
the lifetime control portion is provided between a second peak second closest to the back surface of the semiconductor substrate and a third peak third closest to the back surface out of the four peaks in the depth direction of the semiconductor substrate.

16. The semiconductor device according to claim 13, wherein
the lifetime control portion has a peak of the lifetime killer concentration at a position that is 10 μm or more and 15 μm or less from the back surface of the semiconductor substrate in the depth direction of the semiconductor substrate.

17. The semiconductor device according to claim 1, wherein
the lifetime control portion contains helium.

18. The semiconductor device according to claim 1, wherein
the main region is sandwiched between decay regions including the decay region in a trench array direction.

19. The semiconductor device according to claim 1, wherein
the main region is enclosed by the decay region in the direction parallel to the front surface of the semiconductor substrate.

20. The semiconductor device according to claim 1, wherein
the main region occupies 80% or more of a width of the diode portion in a trench array direction.

21. The semiconductor device according to claim 1, wherein
a width of the decay region is 0.1 μm or more and 10.0 μm or less in a trench array direction.

22. The semiconductor device according to claim 1, wherein
a width of the decay region is a diffusion half width at half maximum by which a lifetime killer for forming the main region is diffused.

23. The semiconductor device according to claim 1, wherein
the main region has a uniform doping concentration in the direction parallel to the front surface of the semiconductor substrate.

24. The semiconductor device according to claim 1, wherein
the transistor portion includes a boundary region provided in direct contact with the diode portion, and
the boundary region includes a base region of the second conductivity type on the front surface.

25. The semiconductor device according to claim 1, wherein
the transistor portion includes a boundary region provided in direct contact with the diode portion, and
the boundary region includes a contact region of the second conductivity type, which has a higher doping concentration than a base region of the second conductivity type provided on the front surface.

26. A manufacturing method of a semiconductor device including a transistor portion and a diode portion, comprising:
forming a drift region of a first conductivity type in a semiconductor substrate;
forming a collector region of a second conductivity type on a back surface of the semiconductor substrate;
forming a cathode region of the first conductivity type, which has a higher doping concentration than the drift region, on the back surface of the semiconductor substrate;
forming a plurality of trench portions on a front surface of the semiconductor substrate; and
forming a lifetime control portion containing a lifetime killer in the semiconductor substrate,
wherein the forming the lifetime control portion includes:
forming a main region in the diode portion; and
forming a decay region which extends from the main region in a direction parallel to the front surface of the semiconductor substrate and has a lifetime killer concentration that has decayed more than a lifetime killer concentration of the main region.

27. A manufacturing method of a semiconductor device including a transistor portion and a diode portion, comprising:
forming a drift region of a first conductivity type in a semiconductor substrate;
forming a collector region of a second conductivity type on a back surface of the semiconductor substrate;
forming a cathode region of the first conductivity type, which has a higher doping concentration than the drift region, on the back surface of the semiconductor substrate;
forming a plurality of trench portions on a front surface of the semiconductor substrate; and
forming a lifetime control portion containing a lifetime killer in the semiconductor substrate,
wherein the lifetime control portion extends from an inside of the cathode region in a direction parallel to the front surface of the semiconductor substrate, and is terminated without extending to a boundary between the collector region and the cathode region in a top view.

28. The manufacturing method of a semiconductor device according to claim 26, wherein
the forming the lifetime control portion includes forming a mask on the semiconductor substrate in order to form the lifetime killer, and
an overlapping width by which the mask overlaps with the diode portion is equal to or larger than a diffusion half width at half maximum by which the lifetime killer is diffused in a top view.

29. The manufacturing method of a semiconductor device according to claim 28, wherein
the forming the lifetime control portion includes implanting the lifetime killer via a uniform mask opening portion where the mask is not formed.
